(19) United States
(12) Patent Application Publication
(10) Pub. No.: US 2026/0173758 A1
(43) Pub. Date: Jun. 18, 2026

(54) THERMOELECTRIC DEVICE INCLUDING DIFFUSION BARRIER LAYER AND HOME APPLIANCE INCLUDING THE SAME

(71) Applicant: SAMSUNG ELECTRONICS CO., LTD, Suwon-si (KR)

(72) Inventors: Kyunghwan LEE, Suwon-si (KR); Jinju KIM, Suwon-si (KR); Kwangjoo KIM, Suwon-si (KR)

(73) Assignee: SAMSUNG ELECTRONICS CO., LTD., Suwon-si (KR)

(21) Appl. No.: 19/391,326

(22) Filed: Nov. 17, 2025

Related U.S. Application Data
(63) Continuation of application No. PCT/KR2025/016932, filed on Oct. 23, 2025.

(30) Foreign Application Priority Data
Dec. 18, 2024 (KR) 10-2024-0189667

(51) Int. Cl. H10N 10/80; H10N 10/01; H10N 10/10

(52) U.S. Cl. CPC H10N 10/80; H10N 10/01; H10N 10/10

(57) ABSTRACT

A thermoelectric element may include: a Bi—Te based thermoelectric leg; a first diffusion barrier layer disposed on an upper side and/or a lower side of the thermoelectric leg, the first diffusion barrier layer including: a multi-layer including a plurality of stacked alloy layers, each of the stacked alloy layers having a thickness of 1 nm to 30 nm and including a nickel (Ni)-chromium (Cr) alloy or a nickel (Ni)-vanadium (V) alloy, and a second diffusion barrier layer disposed on a side of the first diffusion barrier layer, the second diffusion barrier layer including gold (Au), silver (Ag), tin (Sn), or a combination thereof.

### CROSS-REFERENCE TO RELATED APPLICATIONS

This application is a by-pass continuation application of International Application No. PCT/KR2025/016932, filed on Oct. 23, 2025, which is based on and claims priority to Korean Patent Application No. 10-2024-0189667, filed on Dec. 18, 2024, in the Korean Intellectual Property Office, the disclosures of which are incorporated by reference herein their entireties.

### TECHNICAL FIELD

An embodiment disclosed in the disclosure relates to a thermoelectric element including a diffusion barrier layer and a home appliance including the same.

### BACKGROUND ART

Generally, a thermoelectric element is called by various names such as a thermoelectric module, a Peltier element, a thermoelectric cooler (TEC), or a thermoelectric module (TEM). A thermoelectric element is composed of N-type and P-type thermoelectric materials (thermoelectric legs) and electrodes such as nickel (Ni) and cobalt (Co). A thermoelectric element may include a diffusion barrier layer, and the diffusion barrier layer is mainly disposed between a thermoelectric semiconductor element and an electrode, thereby limiting mutual diffusion between the thermoelectric material and the electrode.

When a direct current (DC) voltage is applied to two opposite ends of a thermoelectric element, heat moves from a heat absorbing portion to a heat generating portion according to a flow of electrons in the N-type thermoelectric material and according to a flow of holes in the P-type thermoelectric material. In some cases, when the polarity of an applied voltage is changed, positions of the heat absorbing portion and the heat generating portion are switched with each other, and a flow of heat is also reversed. Through this principle, a thermoelectric element may provide a role of a heat pump that absorbs heat from a low-temperature heat source and provides heat to a high-temperature heat source, or provide a role of a thermoelectric generation (TEG) that generates an electromotive force by moving electrons and holes inside thermoelectric element due to a temperature difference between two opposite ends.

### DISCLOSURE OF INVENTION

### Solution to Problems

A thermoelectric element according to an embodiment of the present disclosure may include: a Bi—Te based thermoelectric leg; a first diffusion barrier layer disposed on an upper side and/or a lower side of the thermoelectric leg, the first diffusion barrier layer may comprising: a multi-layer including a plurality of stacked alloy layers, each of the stacked alloy layers may have a thickness of 1 nm to 30 nm and may include a nickel (Ni)-chromium (Cr) alloy or a nickel (Ni)-vanadium (V) alloy; and a second diffusion barrier layer disposed on a side of the first diffusion barrier layer, the second diffusion barrier layer may include gold (Au), silver (Ag), tin (Sn), or a combination thereof.

A refrigerator according to an embodiment of the present disclosure: a main body; a storage compartment inside the main body, and configured to store food; a door rotatably connected to open or close the main body; a storage compartment disposed inside the main body for storing; and a cold air supply device configured to supply cold air to the storage compartment, the cold air supply device including thermoelectric element that includes: a Bi—Te based thermoelectric leg, a first diffusion barrier layer disposed on an upper and/or a lower side of the thermoelectric leg, the first diffusion barrier layer ma include: a multi-layer structure that may include a plurality of stacked alloy layers, each of the stacked alloy layers may have a thickness of 1 nm to 30 nm and may include a nickel (Ni)-chromium (Cr) alloy or a nickel (Ni)-vanadium (V) alloy, and a second diffusion barrier layer disposed on a side of the first diffusion barrier layer, the second diffusion barrier layer may include gold (Au), silver (Ag), tin (Sn), or a combination thereof.

A method of manufacturing a thermoelectric element including a Bi—Te based thermoelectric leg, a first diffusion barrier layer on a side of the thermoelectric leg, the first diffusion barrier layer including: a multi-layer structure including a plurality of stacked alloy layers, each of the stacked alloy layers including a nickel (Ni)-chromium (Cr) alloy or a nickel (Ni)-vanadium (V) alloy, and a second diffusion barrier layer on a side of the first diffusion barrier layer, the second diffusion barrier layer including gold (Au), silver (Ag), tin (Sn), or a combination thereof, may include: plasma cleaning the thermoelectric leg, depositing the first diffusion barrier layer on the thermoelectric leg with a first sputtering unit, and depositing the second diffusion barrier layer on the first diffusion barrier layer with a second sputtering unit.

The disclosure is not limited to the foregoing embodiments but various modifications or changes may rather be made thereto without departing from the spirit and scope of the disclosure.

### BRIEF DESCRIPTION OF DRAWINGS

FIG. 1 is a perspective view illustrating a thermoelectric element in which diffusion barrier layers are stacked according to an embodiment of the disclosure.

FIG. 2 is a view illustrating a cross-section of a thermoelectric element in which a plurality of layers are stacked and enlarged views of some layers according to an embodiment of the disclosure.

FIG. 3 is a view illustrating a cross-section of a thermoelectric element in which a plurality of layers are stacked and enlarged views of some layers according to an embodiment of the disclosure.

FIG. 4 is a view illustrating a cross-section of a portion of a thermoelectric element in which a plurality of layers are stacked, taken using equipment according to an embodiment of the disclosure.

FIG. 5 is a view illustrating a cross-section of a thermoelectric element in which a plurality of layers are stacked, taken using equipment according to an embodiment of the disclosure.

FIGS. 6A and 6B are flowcharts illustrating a manufacturing process of a thermoelectric element according to an embodiment of the disclosure.

FIGS. 7A, 7B, 7C, and 7D are views illustrating equipment for multi-layer deposition of a diffusion barrier layer during a manufacturing process of a thermoelectric element according to an embodiment of the disclosure.

FIG. 8 is a graph illustrating experimental results of adhesive strength between a diffusion barrier layer configured as a single-layer and a diffusion barrier layer configured as a multi-layer according to an embodiment of the disclosure.

FIG. 9 is a view illustrating a comparative experiment related to thickness of a first diffusion barrier layer of a thermoelectric element according to an embodiment of the disclosure.

FIG. 10 is a perspective view illustrating a refrigerator according to an embodiment of the disclosure;

### MODE FOR THE INVENTION

It should be appreciated that various embodiments of the disclosure and the terms used therein are not intended to limit the technological features set forth herein to particular embodiments and include various changes, equivalents, or replacements for a corresponding embodiment.

With regard to the description of the drawings, similar reference numerals may be used to refer to similar or related elements.

It is to be understood that a singular form of a noun corresponding to an item may include one or more of the things, unless the relevant context clearly indicates otherwise.

As used herein, each of such phrases as “A or B,” “at least one of A and B,” “at least one of A or B,” “A, B, or C,” “at least one of A, B, and C,” and “at least one of A, B, or C,” may include all possible combinations of the items enumerated together in a corresponding one of the phrases.

In the disclosure, the term “and/or” may denote a combination(s) of a plurality of related components as listed or any of the components.

In the disclosure, such terms as “1st” and “2nd,” or “first” and “second” may be used to simply distinguish a corresponding component from another, and does not limit the components in other aspect (e.g., importance or order).

In the disclosure, the terms ‘front surface,’ ‘rear surface,’ ‘upper surface,’ ‘side surface,’ ‘left side,’ ‘right side,’ ‘upper portion,’ and ‘lower portion’ are defined with respect to the drawings, and the shape and position of each component are not limited by the terms.

It is to be understood that if an element (e.g., a first element) is referred to, with or without the term “operatively” or “communicatively”, as “coupled with,” “coupled to,” “connected with,” or “connected to” another element (e.g., a second element), it means that the element may be coupled with the other element directly (e.g., wiredly), wirelessly, or via a third element.

It will be further understood that the terms “comprise” and/or “have,” as used herein, specify the presence of stated features, integers, steps, operations, elements, and/or components, but do not preclude the presence or addition of one or more other features, integers, steps, operations, elements, components, and/or groups thereof.

It will be understood that when a component is referred to as “connected to,” “coupled to”, “supported on,” or “contacting” another component, the components may be connected to, coupled to, supported on, or contact each other directly or via a third component.

Throughout the specification, when one component is positioned “on” another component, the first component may be positioned directly on the second component, or other component(s) may be positioned between the first and second component.

The refrigerator according to an embodiment may include a main body.

The “main body” may include an inner case, an outer case disposed outside the inner case, and an insulator provided between the inner case and the outer case.

The “inner case” may include at least one of a case, a plate, a panel, or a liner forming a storage compartment. The inner case may be formed as a single body or may be formed by assembling a plurality of plates. The “outer case” may form the outer appearance of the main body and may be coupled to an outer side of the inner case so that the insulator is disposed between the inner case and the outer case.

The “insulator” may insulate the inside of the storage compartment and the outside of the storage compartment so that the temperature inside the storage compartment is maintained at a set appropriate temperature without being affected by the environment outside the storage compartment. According to an embodiment, the insulator may include a foam insulator. The foam insulator may be formed by injecting and foaming a urethane foam formed by mixing polyurethane and a foaming agent between the inner case and the outer case.

According to an embodiment, the insulator may further include a vacuum insulator in addition to the foam insulator, or the insulator may be composed of only a vacuum insulator instead of the foam insulator. The vacuum insulation material may include a core material and an outer cover material that accommodates the core material and seals the inside at a pressure close to vacuum or vacuum. However, the insulator is not limited to the foam insulator or the vacuum insulator, and may include various materials that may be used for insulation.

The “storage compartment” may include a space limited by the inner case. The storage compartment may further include an inner case that limits a space corresponding to the storage compartment. Various items such as food, medicine, cosmetics, etc. may be stored in the storage compartment, and the storage compartment may be formed so that at least one side thereof is opened to take in and out the items.

The refrigerator may include one or more storage compartments. When two or more storage compartments are formed in the refrigerator, each storage compartment may have a different use and may be maintained at a different temperature. To that end, each storage compartment may be partitioned from each other by a partition wall including an insulator.

The storage compartment may be provided to be maintained in an appropriate temperature range according to the use, and may include a “refrigerating compartment”, a “freezing compartment”, or an “adjustable-temperature compartment” divided by the use and/or temperature range thereof. The refrigerating compartment may be maintained at a temperature suitable for refrigerating and storing items, and the freezing compartment may be maintained at a temperature suitable for freezing and storing items. The term “refrigerating” may mean cooling the item to the extent that the item is not frozen, and for example, the refrigerating compartment may be maintained in the range of 0 degrees Celsius to 7 degrees Celsius. The term “freezing” may mean cooling the item to freeze or remain frozen, and for example, the freezing compartment may be maintained in the range of minus 20 degrees Celsius to minus 1 degree Celsius. The adjustable-temperature compartment may be used as any one of the refrigerating compartment or the freezing compartment regardless of the user's selection.

The storage compartment may be referred to as a “vegetable compartment”, a “fresh compartment”, a “cooling compartment”, an “ice-making compartment”, and the like, in addition to the names “refrigerating compartment”, “freezing compartment”, and “adjustable-temperature compartment”, and the terms “refrigerating compartment”, “freezing compartment”, and “adjustable-temperature compartment” used below should be understood to collectively mean storage compartments having their respective corresponding uses and temperature ranges.

According to an embodiment, the refrigerator may include at least one door configured to open and close one open side of the storage compartment. The door may be provided to open and close each of one or more storage compartments, or one door may be provided to open and close a plurality of storage compartments. The door may be rotatably or slidably installed on the front surface of the main body.

The “door” may be configured to seal the storage compartment when the door is closed. Like the main body, the door may include an insulator to insulate the storage compartment when the door is closed.

According to an embodiment, the door may include a door outer plate forming a front surface of the door, a door inner plate forming a rear surface of the door and facing the storage compartment, an upper cap, a lower cap, and a door insulator provided thereinside.

A gasket may be provided on the edge of the door inner plate to seal the storage compartment by being in close contact with the front surface of the main body when the door is closed. The door inner plate may include a dyke protruding rearward to mount a door basket capable of storing an object.

According to an embodiment, the door may include a door body and a front panel detachably coupled to a front side of the door body and forming a front surface of the door. The door body may include a door outer plate forming a front surface of the door body, a door inner plate forming a rear surface of the door body and facing the storage compartment, an upper cap, a lower cap, and a door insulator provided thereinside.

The refrigerator may be classified into a French door type, a side-by-side type, a bottom mounted freezer (BMF), a top mounted freezer (TMF), or a one-door refrigerator according to the arrangement of the door and the storage compartment.

According to an embodiment, the refrigerator may include a cold air supply device configured to supply cold air to the storage compartment.

The “cold air supply device” may include a machine, an instrument, an electronic device, and/or a system combining the machine, the instrument, and the electronic device capable of generating cold air and guiding the cold air to cool the storage compartment.

According to an embodiment, the cold air supply device may generate cold air through a refrigerating cycle including processes of compressing, condensing, expanding, and evaporating the refrigerant. To that end, the cold air supply device may include a refrigerating cycle device having a compressor, a condenser, an expansion device, and an evaporator capable of driving the refrigerating cycle. According to an embodiment, the cold air supply device may include a semiconductor such as a thermoelectric element. The thermoelectric element may cool the storage compartment by heating and cooling through the Peltier effect.

According to an embodiment, the refrigerator may include a machine room in which at least some components belonging to the cold air supply device are arranged.

The “machine room” may be provided to be partitioned and insulated from the storage compartment to prevent heat generated from components disposed in the machine room from being transferred to the storage compartment. The inside of the machine room may be configured to communicate with the outside of the main body to dissipate heat from components disposed inside the machine room.

According to an embodiment, the refrigerator may include a dispenser provided on the door to provide water and/or ice. The dispenser may be provided on the door to be accessed by the user without opening the door.

According to an embodiment, the refrigerator may include an ice maker provided to generate ice. The ice maker may include an ice-making tray storing water, an ice maker separating ice from the ice-making tray, and an ice bucket storing ice generated in the ice-making tray.

According to an embodiment, the refrigerator may include a controller for controlling the refrigerator.

The “controller” may include a memory storing or recording a program and/or data for controlling the refrigerator, and a processor outputting a control signal for controlling the cold air supply device according to the program and/or data stored in the memory.

The memory stores or records various information, data, instructions, programs, etc. necessary for the operation of the refrigerator. The memory may store temporary data generated while generating a control signal for controlling components included in the refrigerator. The memory may include at least one of a volatile memory and a non-volatile memory or a combination thereof.

The processor controls the overall operation of the refrigerator. The processor may control the components of the refrigerator by executing a program stored in the memory. The processor may include a separate NPU that performs the operation of the artificial intelligence model. The processor may include a central processing unit, a graphics-only processor (GPU), and the like. The processor may generate a control signal for controlling the operation of the cold air supply device. For example, the processor may receive temperature information about the storage compartment from the temperature sensor, and generate a cooling control signal for controlling the operation of the cold air supply device based on the temperature information about the storage compartment.

Further, the processor may process the user input of the user interface according to the program and/or data recorded/stored in the memory, and control the operation of the user interface. The user interface may be provided using an input interface and an output interface. The processor may receive a user input from the user interface. Further, the processor may transfer a display control signal and image data for displaying an image on the user interface to the user interface in response to the user input.

The processor and the memory may be provided integrally or separately. The processor may include one or more processors. For example, the processor may include a main processor and at least one sub-processor. The memory may include one or more memories.

The refrigerator may include a processor and a memory controlling all components included in the refrigerator, and a plurality of processors and a plurality of memories individually controlling the components of the refrigerator. For example, the refrigerator may include a processor and a memory controlling the operation of the cold air supply device according to the output of the temperature sensor. Further, the refrigerator may include a separate processor and a separate memory controlling the operation of the user interface according to a user input.

The communication module may communicate with an external device such as a server, a mobile device, another home appliance, or the like through an access point (AP). The AP may connect the local area network (LAN) to which the refrigerator or the user equipment is connected to the wide area network (WAN) to which the server is connected. The refrigerator or the user device may be connected to the server through the wide area network (WAN).

The input interface may include a key, a touch screen, a microphone, and the like. The input interface may receive a user input and transfer the user input to the processor.

The output interface may include a display, a speaker, and the like. The output interface may output various notifications, messages, information, and the like generated by the processor.

Hereinafter, embodiments of the disclosure are described in detail with reference to the accompanying drawings.

Meanwhile, the terms “upper”, “lower”, “front”, and “rear” used in the following description are defined with respect to the drawings, and the shape and position of each component are not limited by these terms. For example, the terms “front” and “rear” below may mean the front and rear, respectively, of the refrigerator in the X direction with respect to the drawings. The terms “upper” and “lower” below may mean upper and lower, respectively, in the Z direction of the refrigerator with respect to the drawings. The terms “left” and “right” below may mean the left and right, respectively, in the Y direction of the refrigerator with respect to the drawings.

Hereinafter, a thermoelectric semiconductor (hereinafter, thermoelectric element) used in a cold air supply device is described. The thermoelectric element is described as a semiconductor for cooling a storage compartment of a refrigerator, but is not limited thereto, and may be easily modified and applied to various home appliances in which thermoelectric elements are utilized, such as an air purifying humidifier, a robot cleaner, a cooking device, or a washer.

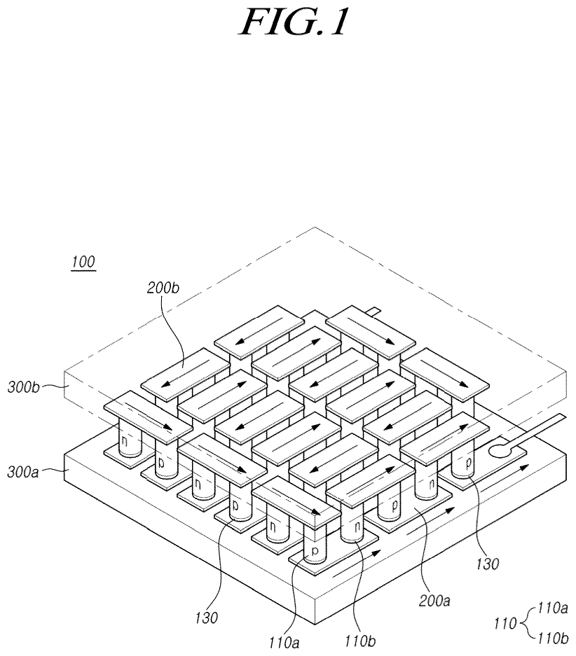

FIG. 1 is a perspective view illustrating a thermoelectric element in which diffusion barrier layers are stacked according to an embodiment of the disclosure.

Referring to FIG. 1, a thermoelectric element 100 may include a thermoelectric leg 110 (e.g., thermoelectric material) in which at least one diffusion barrier layer 130 is stacked. The at least one diffusion barrier layer 130 may be formed on thermoelectric leg 110 by a dry deposition process.

According to an embodiment, the thermoelectric element 100 may include a first substrate 300a, a second substrate 300b disposed in parallel with the first substrate 300a, a first electrode 200a disposed on the first substrate 300a, a second electrode 200b disposed on the second substrate 300b, and a thermoelectric leg 110 disposed between the first electrode 200a and the second electrode 200b. The first electrode 200a and the second electrode 200b may be disposed between the first substrate 300a and the second substrate 300b. The first electrode 200a and the second electrode 200b form a designated pattern, and a plurality of the electrodes may be disposed.

According to an embodiment, the first substrate 300a and the second substrate 300b may each cause a heat generation reaction or a heat absorption reaction when power is applied to the thermoelectric element 100. The first substrate 300a and the second substrate 300b may each be formed in a plate shape and formed of various materials. According to an embodiment, the first substrate 300a and/or the second substrate 300b may be formed of a non-conductive material such as ceramic or insulating resin. For example, the first substrate 300a and/or the second substrate 300b may be at least one of Al₂O₃, AlN, SiC, or ZrO₂ or a combination thereof. According to an embodiment, the first substrate 300a and/or the second substrate 300b may be a substrate of a conductive material (e.g., metal) capable of conducting electricity. For example, the first substrate 300a and/or the second substrate 300b may be one of aluminum (Al), zinc (Zn), copper (Cu), nickel (Ni), or cobalt (Co) or a combination thereof. When the first substrate 300a and/or the second substrate 300b are formed of a conductive material, an insulation layer may be disposed between the substrates 300a, 300b and the electrodes 200a, 200b so as not to be electrically connected to the electrodes 200a, 200b.

According to an embodiment, the first substrate 300a and the second substrate 300b are disposed to face each other, a plurality of first electrodes 200a are disposed on an inner surface of the first substrate 300a, and a plurality of second electrodes 200b may be disposed on an inner surface of the second substrate 300b. The first electrode 200a and the second electrode 200b are disposed so that at least portions thereof face each other, and may be formed of a conductive material (e.g., metallic material) through which current may move. For example, the first electrode 200a and/or the second electrode 200b may be one of aluminum (Al), zinc (Zn), copper (Cu), cobalt (Co), nickel (Ni), gold (Au), silver (Ag), copper (Cu), or titanium (Ti) or a combination thereof. The first electrode 200a and the second electrode 200b may be formed of the same type of material or different types of materials.

According to an embodiment, the first electrode 200a and/or the second electrode 200b may form a pattern of a designated shape. For example, the plurality of first electrodes 200a may be disposed at designated intervals on the first substrate 300a. For example, the plurality of second electrodes 200b may be disposed at designated intervals on the second substrate 300b. The arrangement of the plurality of first electrodes 200a and the plurality of second electrodes 200b is not limited to the pattern disclosed in FIG. 1, and may be modified to various patterns capable of easily transmitting current.

According to an embodiment, the plurality of thermoelectric legs 110 may each be disposed between the first electrode 200a and the second electrode 200b. Each thermoelectric leg 110 may have one side connected to the first electrode 200a and the other side connected to the second electrode 200b. The thermoelectric leg 110 includes a plurality of P-type thermoelectric legs 110a and a plurality of N-type thermoelectric legs 110b, and the P-type thermoelectric legs 110 and the N-type thermoelectric legs 110 may be alternately disposed in one direction.

According to an embodiment, the P-type thermoelectric legs 110a adjacent to each other in one direction may have upper and lower surfaces electrically connected in series with the first electrode 200a and the second electrode 200b. According to an embodiment, the N-type thermoelectric legs 110 adjacent to each other in one direction may have upper and lower surfaces electrically connected in series with the first electrode 200a and the second electrode 200b.

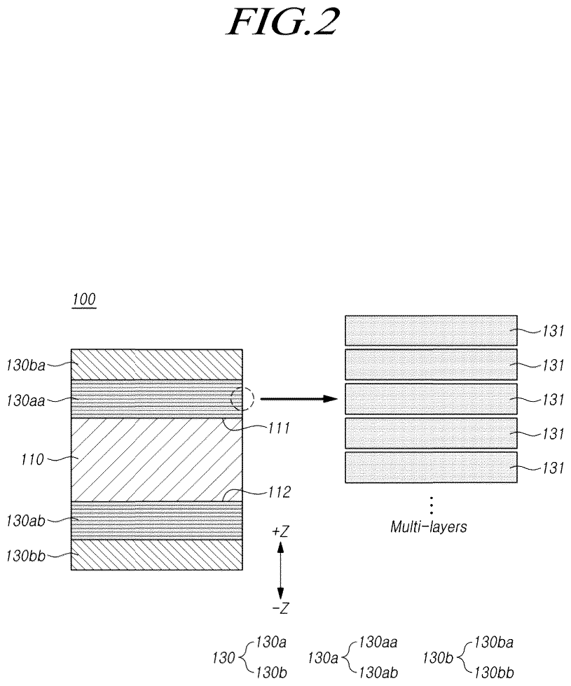

According to an embodiment, the thermoelectric leg 110 (e.g., the P-type thermoelectric legs 110a and the N-type thermoelectric legs 110) may include a diffusion barrier layer 130. The diffusion barrier layer 130 may include a first diffusion barrier layer (e.g., the first diffusion barrier layer 130a of FIG. 2) disposed on an upper side and/or a lower side of thermoelectric leg 110 and a second diffusion barrier layer (e.g., the second diffusion barrier layer 130b of FIG. 2) disposed on one side of the first diffusion barrier layer 130a. The first diffusion barrier layer 130a and the second diffusion barrier layer 130b may be composed of different materials.

According to an embodiment, the first electrode 200a and the second electrode 200b of thermoelectric element 100 may be electrically connected to a power supply source. When a DC voltage is applied from the outside, holes of the P-type thermoelectric leg 110a and electrons of the N-type thermoelectric leg 110b move, so that heat generation and heat absorption may occur at two opposite ends of thermoelectric leg 110.

According to an embodiment, at least one of the first electrode 200a and the second electrode 200b of thermoelectric element 100 may be exposed to a heat supply source. When heat is supplied by an external heat supply source, electrons and holes move to generate a current flow in thermoelectric element, thereby causing power generation.

Hereinafter, the diffusion barrier layer 130 of thermoelectric element 100 is described in detail.

FIG. 2 is a view illustrating a cross-section of a thermoelectric element in which a plurality of layers are stacked and enlarged views of some layers according to an embodiment of the disclosure.

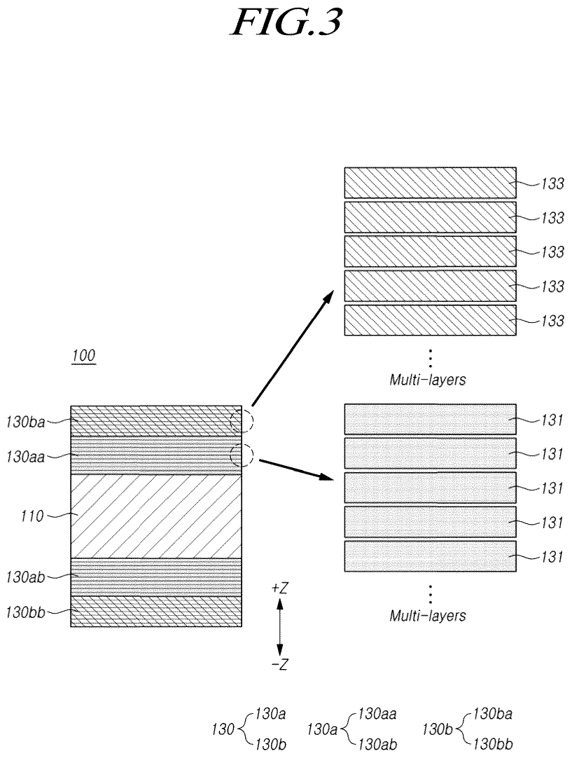

FIG. 3 is a view illustrating a cross-section of a thermoelectric element in which a plurality of layers are stacked and enlarged views of some layers according to an embodiment of the disclosure.

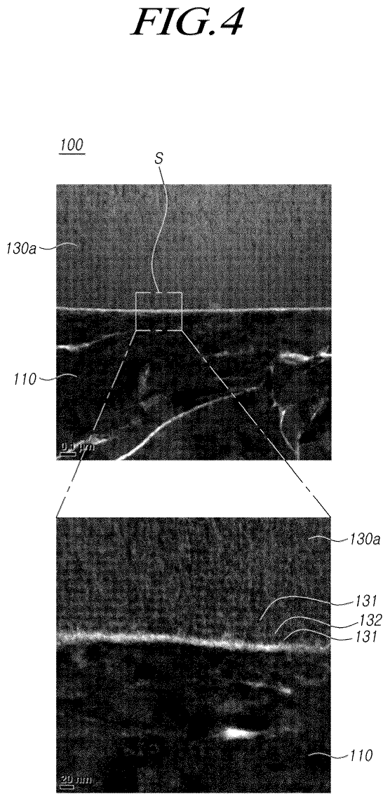

FIG. 4 is a view illustrating a cross-section of a portion of a thermoelectric element in which a plurality of layers are stacked, taken using equipment according to an embodiment of the disclosure.

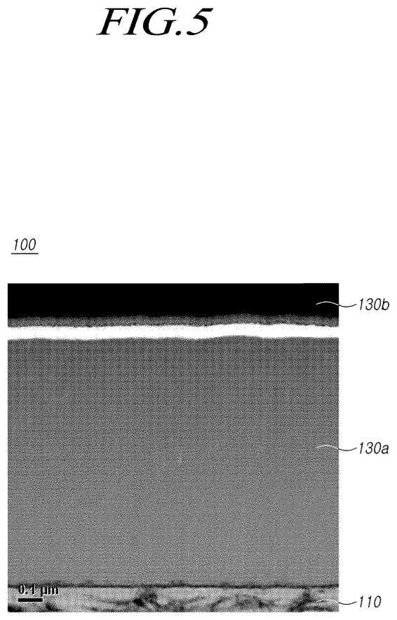

FIG. 5 is a view illustrating a cross-section of a thermoelectric element in which a plurality of layers are stacked, taken using equipment according to an embodiment of the disclosure.

Referring to FIGS. 2 to 5, the thermoelectric element 100 may include a thermoelectric leg 110 (e.g., Peltier leg) and a diffusion barrier layer 130. The diffusion barrier layer 130 may include a first diffusion barrier layer 130a and a second diffusion barrier layer 130b. The configuration of thermoelectric element 100 of FIGS. 2 to 5 may be identical in whole or part to the configuration of thermoelectric element 100 of FIG. 1.

The embodiments of FIGS. 2 to 5 may be selectively combined with the embodiments of FIGS. 1 and 6A to 10.

According to an embodiment, the thermoelectric element 100 may include a thermoelectric leg 110 and a first diffusion barrier layer 130a disposed on an upper side and/or a lower side of thermoelectric leg 110. According to an embodiment, the thermoelectric element 100 may include a thermoelectric leg 110, a first diffusion barrier layer 130a disposed on an upper side and/or a lower side of thermoelectric leg 110, and a second diffusion barrier layer 130b disposed on one side of the first diffusion barrier layer 130a.

According to an embodiment, the thermoelectric leg 110 of thermoelectric element 100 is a thermoelectric semiconductor, and may be a thermoelectric material in which a temperature difference is generated at two opposite ends when electricity is applied, or a thermoelectric material in which electricity is generated by a temperature difference generated at two opposite ends. The thermoelectric leg 110 may be designed in a cylindrical shape. The thermoelectric leg 110 may be the P-type thermoelectric leg 110a or the N-type thermoelectric leg 110 of FIG. 1.

According to an embodiment, a material of the thermoelectric leg 110 may include at least one element selected from the group consisting of transition metals, rare earth elements, Group 13 elements, Group 14 elements, Group 15 elements, or Group 16 elements. For example, the rare earth elements include elements such as Y, Ce, and La, and the transition metal may be one of Ti, Zr, Hf, V, Nb, Ta, Cr, Mo, W, Mn, Fe, Co, Ni, Cu, Zn, Ag, or Re, and an example of the Group 13 element may be one of B, Al, Ga, or In, and an example of the Group 14 element may be one of C, Si, Ge, Sn, or Pb, and an example of the Group 15 element may be one of P, As, Sb, or Bi, and an example of the Group 16 element may be one of S, Se, or Te.

According to an embodiment, the thermoelectric leg 110 may be composed of a composition including at least two or more of bismuth (Bi), tellurium (Te), cobalt (Co), samarium (Sm), antimony (Sb), indium (In), or cerium (Ce). For example, the thermoelectric leg 110 may be at least one of Bi—Te-based, Co—Sb-based, Pb—Te-based, Ge—Te-based, Si—Ge-based, Sb—Te-based, Sm—Co-based, transition metal silicide-based, Skutterudite-based, Silicide-based, or Half-Heusler. For example, the thermoelectric leg 110 may include a (Bi,Sb)₂(Te,Se)₃-based thermoelectric semiconductor in which Sb and Se are used as dopants as a Bi—Te-based thermoelectric semiconductor. For example, the thermoelectric leg 110 may include a CoSb₃-based thermoelectric semiconductor as a Co—Sb-based thermoelectric semiconductor. For example, the thermoelectric leg 110 may include AgSbTe₂ or CuSbTe₂ as a Sb—Te-based thermoelectric semiconductor. For example, the thermoelectric leg 110 may include PbTe or (PbTe)mAgSbTe₂ as a Pb—Te-based thermoelectric semiconductor. The following description is made under the assumption that thermoelectric leg 110 is composed of a Bi—Te-based thermoelectric material.

According to an embodiment, the first diffusion barrier layer 130a may be disposed on an upper side and/or a lower side of thermoelectric leg 110.

According to an embodiment, the first diffusion barrier layer 130a may be selectively disposed on an upper side or a lower side of thermoelectric leg 110. For example, the thermoelectric leg 110 may include a first surface 111 facing a first direction (e.g., +Z-axis direction) and a second surface 112 facing a second direction (e.g., −Z-axis direction) opposite to the first direction (e.g., +Z-axis direction). For example, the first diffusion barrier layer 130a may be disposed on the first surface 111 of the thermoelectric leg 110. The first diffusion barrier layer 130a may be deposited on the first surface 111 of the thermoelectric leg 110. For example, the first diffusion barrier layer 130a may be disposed on the second surface 112 of the thermoelectric leg 110. The first diffusion barrier layer 130a may be deposited on the second surface 112 of the thermoelectric leg 110.

According to an embodiment, the first diffusion barrier layer 130a may be disposed in parallel on upper and lower sides of the thermoelectric leg 110. For example, when the first diffusion barrier layer 130a is disposed on the upper and lower sides of the thermoelectric leg 110, the first diffusion barrier layer 130a may include a 1-1th diffusion barrier layer 130aa disposed on an upper side (e.g., the first surface 111) of the thermoelectric leg 110, and a 1-2th diffusion barrier layer 130ab disposed on a lower side (e.g., the second surface 112) of the thermoelectric leg 110. The 1-1th diffusion barrier layer 130aa and the 1-2th diffusion barrier layer 130ab may be formed with thicknesses and materials corresponding to each other.

According to an embodiment, the first diffusion barrier layer 130a may include one or more metal powders selected from the group consisting of chromium (Cr), nickel (Ni), platinum (Pt), titanium (Ti), tungsten (W), silicon (Si), manganese (Mn), iron (Fe), cobalt (Co), copper (Cu), or molybdenum (Mo) and alloys thereof. However, the material of the first diffusion barrier layer 130a is not limited to the above-mentioned materials, and may be variously modified to metals having a melting point exceeding 1,000° C. or heavy metals.

According to an embodiment, the first diffusion barrier layer 130a may be a Ni—X-based alloy, and the X may be at least one of Cr, V, Al, Co, W, Sn, Zn, or Pb. According to an embodiment, the first diffusion barrier layer 130a may include a nickel (Ni)-chromium (Cr) alloy or a nickel (Ni)-vanadium (V) alloy. For example, the first diffusion barrier layer 130a may form a structure (e.g., multi-layer structure) in which a plurality of nickel (Ni)-chromium (Cr) alloy layers are stacked. For example, the first diffusion barrier layer 130a may form a structure (e.g., multi-layer structure) in which a plurality of nickel (Ni)-vanadium (V) alloy layers are stacked.

According to an embodiment, the first diffusion barrier layer 130a may be a Ni—X-based alloy, and a content of the X may be relatively small compared to a content of Ni. According to an embodiment, in the first diffusion barrier layer 130a formed of a nickel (Ni)-chromium (Cr) alloy, an alloy amount of chromium (Cr) may be 20±10 weight percent (wt %) relative to total weight. For example, in the first diffusion barrier layer 130a, an alloy amount of chromium (Cr) may be about 20 weight percent (wt %) relative to total weight. According to an embodiment, in the first diffusion barrier layer 130a formed of a nickel (Ni)-vanadium (V) alloy, an alloy amount of vanadium (V) may be 10±5 weight percent (wt %) relative to total weight. For example, in the first diffusion barrier layer 130a, an alloy amount of vanadium (V) may be about 7 weight percent (wt %) relative to total weight.

According to an embodiment, the first diffusion barrier layer 130a may constitute a multi-layer in which a plurality of first alloy layers 131 are stacked. The first alloy layer 131 may include the above-mentioned nickel (Ni)-chromium (Cr) alloy or nickel (Ni)-vanadium (V) alloy. Each of the first alloy layers 131 forming the multi-layer may have a thickness of about 30 nm or less. For example, each of the first alloy layers 131 may have a thickness of about 1.0 nm to 30.0 nm. For example, each of the first alloy layers 131 may have a thickness of about 2.0 nm to 30.0 nm. For example, each of the first alloy layers 131 may have a thickness of about 13.0 nm to 15.0 nm.

According to an embodiment, the first diffusion barrier layer 130a includes a plurality of stacked first alloy layers 131, and a total thickness of the first diffusion barrier layer 130a may be a sum of thicknesses of the first alloy layers 131. According to an embodiment, a total thickness of the first diffusion barrier layer 130a may be greater than a total thickness of the second diffusion barrier layer 130b. According to an embodiment, a total thickness of the first diffusion barrier layer 130a may be smaller than a thickness of the thermoelectric leg 110. A thickness of the first diffusion barrier layer 130a may have a thickness of about 10.0 μm or less. For example, a thickness of the first diffusion barrier layer 130a may have about 1.0 μm to 10.0 μm. For example, a thickness of the first diffusion barrier layer 130a may have about 3.0 μm to 5.0 μm.

According to an embodiment, the first diffusion barrier layer 130a has a structure in which a plurality of stacked first alloy layers 131 are stacked, and may be stacked on thermoelectric leg 110 by a dry deposition process. For example, the first diffusion barrier layer 130a may have a structure in which about 100 to 1000 first alloy layers 131 are stacked. For example, the first diffusion barrier layer 130a may have a structure in which about 200 to 400 first alloy layers 131 are stacked.

According to an embodiment, the first diffusion barrier layer 130a may minimize internal stress by depositing each of the first alloy layers 131 on upper and/or lower sides of the thermoelectric leg 110 through a dry deposition process. Generally, when direct tin (Sn) soldering is performed on a thermoelectric leg (e.g., Bi—Te-based thermoelectric material), a Sn—Te-based intermetallic compound (IMC) is formed by thermal diffusion, causing brittleness and frequent thermoelectric element destruction. In the thermoelectric element 100 of the disclosure, a sputtering process is performed when depositing the first alloy layers 131 on the thermoelectric leg 110, and a multi-layer is formed by providing a cooling time for a designated interval after one first alloy layer 131 is deposited, thereby minimizing internal stress of the thermoelectric element 100. The internal stress minimization may enhance long-term durability of the thermoelectric element 100 by increasing adhesive strength between the thermoelectric leg 110 and the first diffusion barrier layer 130a.

According to an embodiment, the first diffusion barrier layer 130a may be formed as a multi-layer in which a plurality of first alloy layers 131 are stacked. When the first alloy layers 131 are deposited on thermoelectric leg 110, after a sputtering process, a cooling time is provided, so that the first alloy layers 131 adjacent to each other may form an interlayer interface 132 that facilitates interlayer distinction.

Referring to FIG. 4, an enlarged view of the first diffusion barrier layer 130a through analytical equipment may be identified. The analytical equipment used a transmission electron microscope (TEM), and TEM may analyze an internal structure of a material at high resolution using an electron beam. Referring to FIG. 4, the first diffusion barrier layer 130a deposited on thermoelectric leg 110 is illustrated, and in an enlarged view of a portion S of the first diffusion barrier layer 130a, it may be identified that the first diffusion barrier layer 130a forms a multi-layer. For example, the first alloy layers 131 may be distinguishable by forming an interlayer interface 132 to be distinguishable from adjacent first alloy layers 131. The interlayer interface 132 is a process in which a surface of the first alloy layer 131 contacts external air due to a cooling time provided at designated intervals in a sputtering process, and appears in a color distinguishable from an inside of the first alloy layer 131 by TEM photography. The first diffusion barrier layer 130a illustrated in FIG. 4 is a nickel (Ni)-chromium (Cr) alloy layer (or nickel (Ni)-vanadium (V) alloy layer), and a thickness of each alloy layer was identified to be about 13.0 nm to 15.0 nm.

According to an embodiment, the second diffusion barrier layer 130b may be disposed on one side (e.g., upper side or lower side) of the first diffusion barrier layer 130a.

According to an embodiment, the first diffusion barrier layer 130a (e.g., the 1-1th diffusion barrier layer 130aa) disposed on an upper side of the thermoelectric leg 110 may include a first surface facing a first direction (e.g., +Z-axis direction) and a second surface (e.g., one surface facing a −Z-axis) facing a second direction (e.g., −Z-axis direction) opposite to the first direction (e.g., +Z-axis direction). The second diffusion barrier layer 130b may be disposed on the first surface of the 1-1th diffusion barrier layer 130aa. The second diffusion barrier layer 130b may be deposited on the first surface of the 1-1th diffusion barrier layer 130aa.

According to an embodiment, the first diffusion barrier layer 130a (e.g., the 1-2th diffusion barrier layer 130ab) disposed on a lower side of the thermoelectric leg 110 may include a first surface facing a first direction (e.g., +Z-axis direction), and a second surface facing a second direction (e.g., −Z-axis direction) opposite to the first direction (e.g., +Z-axis direction). The second diffusion barrier layer 130b may be disposed on the second surface of the 1-2th diffusion barrier layer 130ab. The second diffusion barrier layer 130b may be deposited on the second surface of the 1-2th diffusion barrier layer 130ab.

According to an embodiment, the first diffusion barrier layer 130a may be disposed in parallel on upper and lower sides of the thermoelectric leg 110. The second diffusion barrier layer 130b may be disposed on a pair of first diffusion barrier layers 130a disposed on upper and lower sides of the thermoelectric leg 110. For example, the second diffusion barrier layer 130b may include a 2-1th diffusion barrier layer 130ba disposed on the 1-1th diffusion barrier layer 130aa disposed on an upper side of the thermoelectric leg 110, and a 2-2th diffusion barrier layer 130bb disposed on the 1-2th diffusion barrier layer 130ab disposed on a lower side of the thermoelectric leg 110. For example, the 1-1th diffusion barrier layer 130aa may be positioned between the thermoelectric leg 110 and the 2-1th diffusion barrier layer 130ba. For example, the a-2th diffusion barrier layer 130ab may be positioned between the thermoelectric leg 110 and the 2-2th diffusion barrier layer 130bb. The 2-1th diffusion barrier layer 130ba and the 2-2th diffusion barrier layer 130bb may be formed with thicknesses and materials corresponding to each other.

According to an embodiment, the second diffusion barrier layer 130b may include one or more metal powders selected from the group consisting of gold (Au), silver (Ag), tin (Sn), chromium (Cr), platinum (Pt), titanium (Ti), tungsten (W), silicon (Si), manganese (Mn), iron (Fe), cobalt (Co), copper (Cu), or molybdenum (Mo).

According to an embodiment, the second diffusion barrier layer 130b may include a layer formed of a single metal. For example, the second diffusion barrier layer 130b may be a single metal layer formed of gold (Au). For example, the second diffusion barrier layer 130b may be a single metal layer formed of silver (Ag). For example, the second diffusion barrier layer 130b may be a single metal layer formed of tin (Sn).

According to an embodiment, a stacked structure of the thermoelectric element 100 including the thermoelectric leg 110, the first diffusion barrier layer 130a, and the second diffusion barrier layer 130b may be designed and modified in various combinations. For example, the thermoelectric element 100 may be composed of a Bi—Te-based thermoelectric leg 110, a first diffusion barrier layer 130a formed of a nickel (Ni)-chromium (Cr) alloy, and a second diffusion barrier layer 130b formed of gold (Au). For example, the thermoelectric element 100 may be composed of a Bi—Te-based thermoelectric leg 110, a first diffusion barrier layer 130a formed of a nickel (Ni)-chromium (Cr) alloy, and a second diffusion barrier layer 130b formed of silver (Ag). For example, the thermoelectric element 100 may be composed of a Bi—Te-based thermoelectric leg 110, a first diffusion barrier layer 130a formed of a nickel (Ni)-chromium (Cr) alloy, and a second diffusion barrier layer 130b formed of tin (Sn). For example, the thermoelectric element 100 may be composed of a Bi—Te-based thermoelectric leg 110, a first diffusion barrier layer 130a formed of a nickel (Ni)-vanadium (V) alloy, and a second diffusion barrier layer 130b formed of gold (Au). For example, the thermoelectric element 100 may be composed of a Bi—Te-based thermoelectric leg 110, a first diffusion barrier layer 130a formed of a nickel (Ni)-vanadium (V) alloy, and a second diffusion barrier layer 130b formed of silver (Ag). For example, the thermoelectric element 100 may be composed of a Bi—Te-based thermoelectric leg 110, a first diffusion barrier layer 130a formed of a nickel (Ni)-vanadium (V) alloy, and a second diffusion barrier layer 130b formed of tin (Sn). However, the above-mentioned stacked configuration of the thermoelectric element 100 is one embodiment and is not limited thereto, and may be variously modified in combinations of various alloy layers and single metal layers.

According to an embodiment, the second diffusion barrier layer 130b may constitute a multi-layer in which a plurality of first single metal layers 133 are stacked. The first single metal layer 133 may include the above-mentioned gold (Au), silver (Ag), or tin (Sn). Each of the first single metal layers 133 forming the multi-layer may have a thickness of about 30 nm or less. For example, each of the first single metal layers 133 may have a thickness of about 1.0 nm to 30.0 nm. For example, each of the first single metal layers 133 may have a thickness of about 2.0 nm to 30.0 nm. For example, each of the first single metal layers 133 may have a thickness of about 13.0 nm to 15.0 nm.

According to an embodiment, the second diffusion barrier layer 130b includes a plurality of stacked first single metal layers 133, and a total thickness of the second diffusion barrier layer 130b may be a sum of thicknesses of the first single metal layers 133. According to an embodiment, a total thickness of the second diffusion barrier layer 130b may be smaller than a total thickness of the first diffusion barrier layer 130a. According to an embodiment, a total thickness of the second diffusion barrier layer 130b may be smaller than a thickness of the thermoelectric material. A thickness of the second diffusion barrier layer 130b may have a thickness of about 3.0 μm or less. For example, a thickness of the second diffusion barrier layer 130b may have about 0.01 μm to 3.0 μm. For example, a thickness of the second diffusion barrier layer 130b may have about 0.01 μm to 0.5 μm. For example, a thickness of the second diffusion barrier layer 130b may have about 0.03 μm to 0.5 μm.

According to an embodiment, the second diffusion barrier layer 130b has a structure in which a plurality of stacked first single metal layers 133 are stacked, and may be deposited on the first diffusion barrier layer 130a by a dry deposition process. For example, the second diffusion barrier layer 130b may have a structure in which about 10 to 300 first single metal layers 133 are stacked. For example, the first diffusion barrier layer 130a may have a structure in which about 50 to 150 first single metal layers 133 are stacked.

According to an embodiment, the second diffusion barrier layer 130b may minimize internal stress by depositing each of the first single metal layers 133 on upper or lower sides of the first diffusion barrier layer 130a through a dry deposition process. In the thermoelectric element 100 of the disclosure, a sputtering process is performed when depositing the first single metal layers 133 on the first diffusion barrier layer 130a (or the thermoelectric leg 110), and a multi-layer is formed by providing a cooling time for a designated interval after depositing one first single metal layer 133, thereby minimizing internal stress. The internal stress minimization may enhance long-term durability of the thermoelectric element 100 by increasing adhesive strength between the first diffusion barrier layer 130a and the second diffusion barrier layer 130b.

Referring to FIG. 5, an enlarged view of the first diffusion barrier layer 130a and the second diffusion barrier layer through analytical equipment may be identified. The analytical equipment used a transmission electron microscope (TEM), and TEM may analyze an internal structure of a material at high resolution using an electron beam. Referring to FIG. 5, the first diffusion barrier layer 130a deposited on thermoelectric leg 110 and the second diffusion barrier layer 130b deposited on the first diffusion barrier layer 130a are illustrated, and it may be identified that each of the first diffusion barrier layer 130a and the second diffusion barrier layer 130b forms a multi-layer. For example, spaces between the first alloy layers 131 constituting the first diffusion barrier layer 130a and spaces between the first single metal layers 133 constituting the second diffusion barrier layer 130b may form interlayer interfaces. The interface is formed by a cooling time provided at designated intervals in a sputtering process, and may minimize internal stress of the diffusion barrier layer. The first diffusion barrier layer 130a illustrated in FIG. 5 is a nickel (Ni)-chromium (Cr) alloy layer (or nickel (Ni)-vanadium (V) alloy layer), and the second diffusion barrier layer 130b was identified to be a single metal layer formed of gold (Au).

According to an embodiment, the thermoelectric element 100 may selectively manufacture the first diffusion barrier layer 130a and/or the second diffusion barrier layer 130b forming a multi-layer.

Referring to FIG. 2, the thermoelectric element 100 may have a structure in which the 1-1th diffusion barrier layer 130aa and the 2-1th diffusion barrier layer 130ba are stacked on an upper side of the thermoelectric leg 110, and the 1-2th diffusion barrier layer 130ab and the 2-2th diffusion barrier layer 130bb are stacked on a lower side of the thermoelectric leg 110. The 1-1th diffusion barrier layer 130aa and the 2-1th diffusion barrier layer 130ba are formed of the same material and may be configured as a multi-layer. The 1-2th diffusion barrier layer 130ab and the 2-2th diffusion barrier layer 130bb are formed of the same material and may be configured as a single layer rather than a multi-layer.

Referring to FIG. 3, the thermoelectric element 100 may have a structure in which the 1-1th diffusion barrier layer 130aa and the 2-1th diffusion barrier layer 130ba are stacked on an upper side of the thermoelectric leg 110, and the 1-2th diffusion barrier layer 130ab and the 2-2th diffusion barrier layer 130bb are stacked on a lower side of the thermoelectric leg 110. The 1-1th diffusion barrier layer 130aa and the 2-1th diffusion barrier layer 130ba are formed of the same material and may be configured as a multi-layer. The 1-2th diffusion barrier layer 130ab and the 2-2th diffusion barrier layer 130bb are formed of the same material and may be configured as a multi-layer.

According to an embodiment, a diffusion barrier layer (e.g., the first diffusion barrier layer 130a and the second diffusion barrier layer 130b) is a layer for limiting diffusion in solder, and may be named as at least one of a diffusion blocking layer, a diffusion suppression layer, a barrier layer, a barrier coating layer, a protective layer, a passivation layer, a solder resist layer, or an anti-oxidation layer.

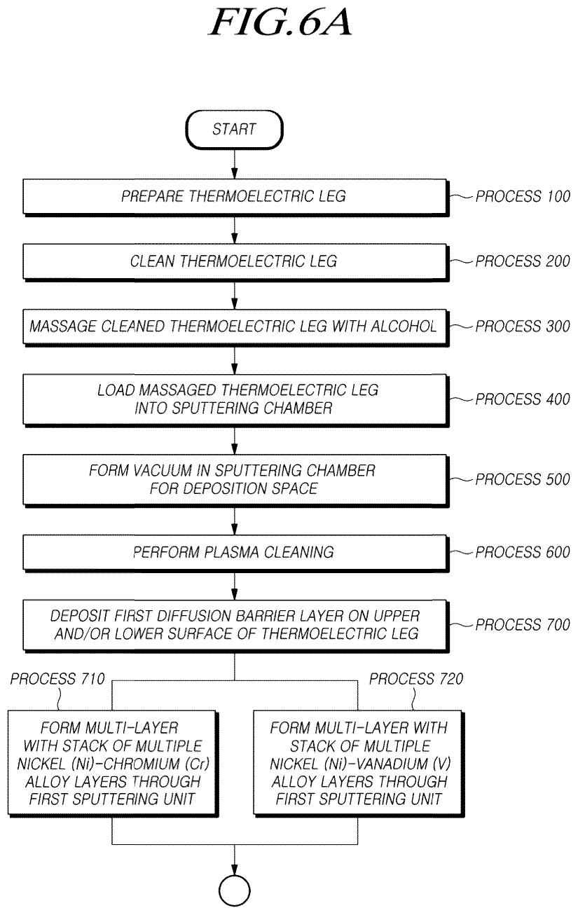

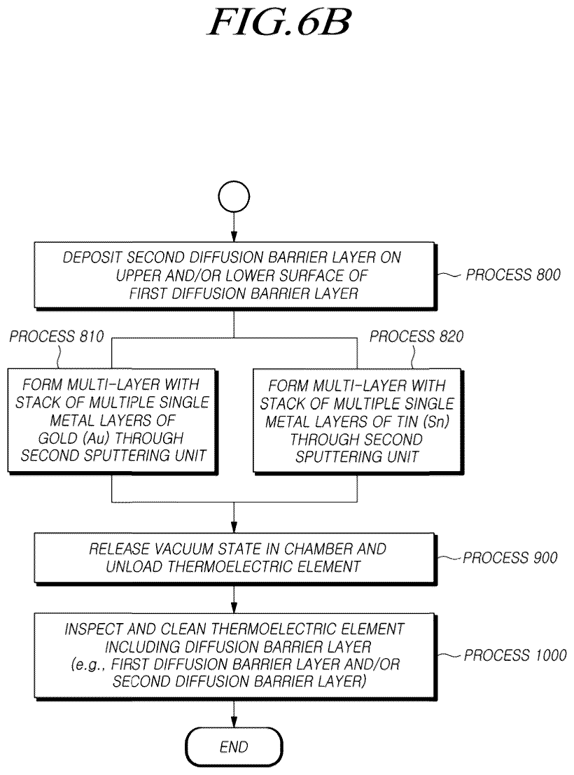

FIGS. 6A and 6B are flowcharts illustrating a manufacturing process of a thermoelectric element according to an embodiment of the disclosure.

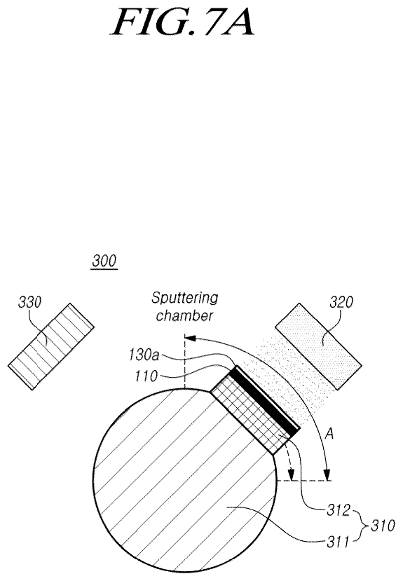

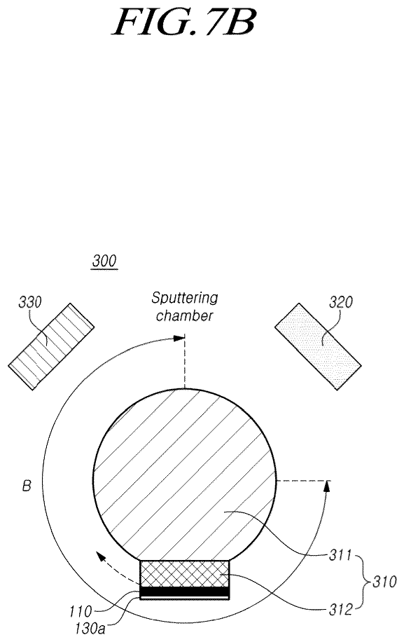

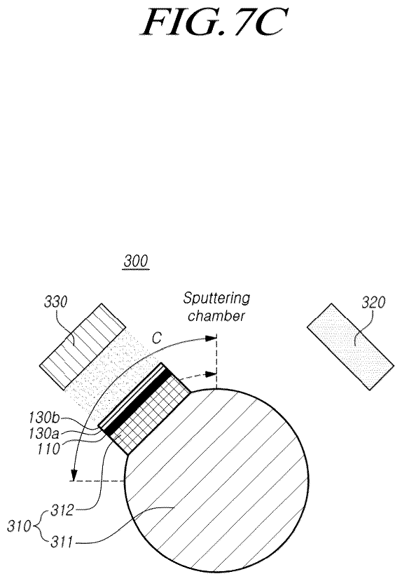

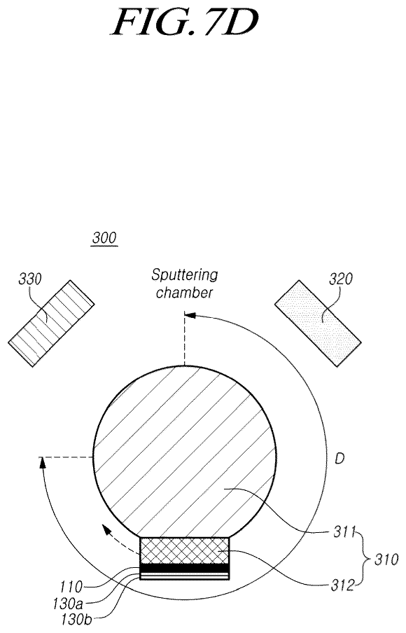

FIGS. 7A, 7B, 7C, and 7D are views illustrating equipment for multi-layer deposition of a diffusion barrier layer during a manufacturing process of a thermoelectric element according to an embodiment of the disclosure.

According to an embodiment, a thermoelectric element (e.g., the thermoelectric element 100 of FIGS. 2 and 3) may include a thermoelectric leg (e.g., the thermoelectric leg 110 of FIGS. 2 and 3), a first diffusion barrier layer (e.g., the first diffusion barrier layer 130a of FIGS. 2 and 3), and/or a second diffusion barrier layer (e.g., the second diffusion barrier layer 130b of FIGS. 2 and 3).

The configuration of the thermoelectric element 100 of FIGS. 6A to 7D may be identical in whole or part to the configuration of the thermoelectric element 100 of FIGS. 1 to 5.

The embodiments of FIGS. 6A to 7D may be selectively combined with the embodiments of FIGS. 1 to 5 and FIG. 10.

Referring to FIGS. 6A to 7D, a process for depositing a diffusion barrier layer 130 on thermoelectric leg 110 of the thermoelectric element 100 is described. The thermoelectric leg 110 may include a P-type thermoelectric leg 110a and an N-type thermoelectric leg 110b, and the P-type thermoelectric leg 110a and the N-type thermoelectric leg 110b on which the deposition process is completed may be alternately disposed between electrodes as illustrated in FIG. 1.

According to process 100, a process of preparing a thermoelectric leg 110 may be performed. The thermoelectric leg 110 may be, e.g., a Peltier leg. The Peltier leg is a main component used in a thermoelectric module using a Peltier effect, and the Peltier effect is a phenomenon in which heat is absorbed or released when current flows between two types of semiconductors (e.g., P-type and N-type semiconductors), thereby creating a temperature difference.

According to an embodiment, the thermoelectric leg 110 may be manufactured or selected in various sizes corresponding to the thermoelectric element 100 in a cylindrical shape. For example, a specification of the cylindrical thermoelectric leg 110 may have a size of about Φ1.8, H2.3 mm or about Φ30, H1.9 mm.

According to an embodiment, a material of the thermoelectric leg 110 may include at least one element selected from the group consisting of transition metals, rare earth elements, Group 13 elements, Group 14 elements, Group 15 elements, or Group 16 elements. For example, the thermoelectric leg 110 may be composed of a composition including at least two or more of bismuth (Bi), tellurium (Te), cobalt (Co), samarium (Sm), antimony (Sb), indium (In), or cerium (Ce). For example, the thermoelectric leg 110 may be at least one of Bi—Te-based, Co—Sb-based, Pb—Te-based, Ge—Te-based, Si—Ge-based, Sb—Te-based, Sm—Co-based, transition metal silicide-based, Skutterudite-based, Silicide-based, or Half-Heusler.

Subsequently, according to process 200, a process of cleaning the thermoelectric leg 110 may be performed. For example, by removing foreign objects (e.g., contaminants or dust) from a surface of the Peltier leg, a deposition surface of the Peltier leg may be kept clean before a deposition process. For example, the cleaning process may be performed so that a state in which a surface of the thermoelectric leg 110 contacts in a cleaning solution (e.g., ethanol stock solution (95% or more)) is maintained, and an immersion time is about 3 min or more and a temperature of the cleaning solution is about 60° C.

Subsequently, according to process 300, a process of massaging the cleaned thermoelectric leg 110 with alcohol may be performed. For example, a process of physically cleaning a surface of the Peltier leg using a tool may be performed. A massage tool may be a microfiber brush or microfiber cloth. The cleaning process may be performed through linear reciprocating motion in horizontal or vertical directions while rubbing the massage tool on a surface of the Peltier leg. Through such cleaning processes (e.g., process 200 and process 300), a surface of the thermoelectric leg 110 may be smoothed and quality of subsequent processes may be ensured.

Subsequently, according to process 400, a process of loading the massaged thermoelectric leg 110 into a sputtering chamber 300 may be performed. A jig 310 to which thermoelectric leg 110 may be fixed is disposed in the sputtering chamber 300, and thermoelectric leg 110 may be mounted on the jig 310. The jig 310 may be formed of a material with high heat resistance and mechanical strength, such as aluminum (Al), polyether ether ketone (PEEK), or stainless steel.

Subsequently, according to process 500, a vacuum formation process for providing a deposition space in the sputtering chamber 300 may be performed. For example, to facilitate deposition on a surface of the thermoelectric leg 110, a vacuum degree may be set to about 6×10⁻⁶ torr or less as an environmental condition of the sputtering chamber 300, and Ar (argon) gas may be used as an internal gas. The environmental conditions may prevent intrusion of external impurities and enhance deposition quality (e.g., quality of the first diffusion barrier layer 130a and the second diffusion barrier layer 130b).

Subsequently, according to process 600, a plasma cleaning process may be performed. The plasma cleaning process may enhance adhesion of deposition layers (e.g., the first diffusion barrier layer 130a and the second diffusion barrier layer 130b) by cleaning surface foreign objects of the thermoelectric leg 110. The plasma cleaning process may enhance adhesion of deposition layers (e.g., the first diffusion barrier layer 130a and the second diffusion barrier layer 130b) by providing fine irregularities on a surface of the thermoelectric leg 110. Plasma cleaning may be performed using O₂ or Ar/O₂ mixed gas with a plasma output of about 100 to 200 W for a processing time of about 5 to 10 min.

Subsequently, according to process 700 (referring to FIGS. 7A and 7B), the first diffusion barrier layer 130a may be deposited on upper and/or lower sides of the thermoelectric leg 110. For example, the first diffusion barrier layer 130a may include a 1-1th diffusion barrier layer (e.g., the 1-1th diffusion barrier layer 130aa of FIG. 3) disposed on an upper side of the thermoelectric leg 110, and a 1-2th diffusion barrier layer (e.g., the 1-2th diffusion barrier layer 130ab of FIG. 3) disposed on a lower side of the thermoelectric leg 110. The 1-1th diffusion barrier layer 130aa and the 1-2th diffusion barrier layer 130ab may be formed with thicknesses and materials corresponding to each other.

According to an embodiment, the first diffusion barrier layer 130a may be a Ni—X-based alloy, and the X may be at least one of Cr, V, Al, Co, W, Sn, Zn, or Pb. According to an embodiment, the first diffusion barrier layer 130a may include a nickel (Ni)-chromium (Cr) alloy or a nickel (Ni)-vanadium (V) alloy. For example, according to process 710, the first diffusion barrier layer 130a may form a structure in which a plurality of nickel (Ni)-chromium (Cr) alloy layers are stacked. For example, according to process 720, the first diffusion barrier layer 130a may form a structure in which a plurality of nickel (Ni)-vanadium (V) alloy layers are stacked. Process 710 or process 720 may be selectively performed.

According to an embodiment, the first diffusion barrier layer 130a is performed by a dry deposition process (e.g., sputtering process), and a sputtering device for this may include a jig 310 and a first sputtering unit 320 spaced apart at an edge portion of the jig 310. Referring to FIGS. 7A and 7B, the jig 310 may include a circular first jig 311 that rotates about a central axis O and a second jig 312 disposed on one side of the first jig 311 for fixing a sample (e.g., the thermoelectric leg 110). For example, the first jig 311 may rotate itself about the central axis O. For example, the second jig 312 is fixedly disposed at an edge of the first jig 311, and may rotate about the central axis O in response to rotation of the first jig 311 while the thermoelectric leg 110 is mounted. The second jig 312 may move past the first sputtering unit 320 and the second sputtering unit 330.

According to an embodiment, in process 700, the thermoelectric leg 110 mounted on the second jig 312 moves to be adjacent to the first sputtering unit 320, and as the first sputtering unit 320 operates, the first diffusion barrier layer 130a may be deposited on the thermoelectric leg 110. For example, as the thermoelectric leg 110 mounted on the second jig 312 rotates and moves, whenever it is adjacent to the first sputtering unit 320 (e.g., when positioned in a first section A, ON time), one layer of a multi-layer (e.g., the first alloy layer 131 of the first diffusion barrier layer 130a) may be deposited on the thermoelectric leg 110 by a first sputtering process. Subsequently, when thermoelectric leg 110 mounted on the second jig 312 additionally rotates and moves away from the first sputtering unit 320 (e.g., when positioned in a second section B, OFF time), a cooling time is provided to one layer of the multi-layer (e.g., the first alloy layer 131 of the first diffusion barrier layer 130a) deposited on the thermoelectric leg 110, and the first alloy layer 131 is stably formed so that internal stress may be decreased. The reduction of the internal stress may limit (reduce or prevent) physical damage (e.g., cracking, warping, or bending) of the first diffusion barrier layer 130a. According to an embodiment, a cooling time may be formed to be longer than a deposition time.

According to an embodiment, a deposition layer (e.g., the first diffusion barrier layer 130a) formed through the first sputtering unit 320 in process 710 may be a multi-layer in which a plurality of nickel (Ni)-chromium (Cr) alloy layers are stacked. One nickel (Ni)-chromium (Cr) alloy layer may be formed when the thermoelectric leg 110 mounted on the second jig 312 rotates once, and the multi-layer may be formed as the thermoelectric leg 110 mounted on the second jig 312 rotates multiple times. For example, when the thermoelectric leg 110 mounted on the second jig 312 rotates multiple times, one layer of the multi-layer may be deposited on the thermoelectric leg 110 by a first sputtering process whenever it is positioned in the first section A adjacent to the first sputtering unit 320 (ON time). A sputtering ON time for depositing one layer on the thermoelectric leg 110 may be about 6.5±2 sec. An alloy amount of chromium (Cr) in the nickel (Ni)-chromium (Cr) alloy layer may be 20±10 weight percent (wt %) relative to total weight. An alloy amount of nickel (Ni) in the nickel (Ni)-chromium (Cr) alloy layer may be 80±10 weight percent (wt %) relative to total weight. For example, when the thermoelectric leg 110 mounted on the second jig 312 rotates multiple times, whenever it is positioned in the second section B away from the first sputtering unit 320 (OFF time), one layer of the multi-layer on the thermoelectric leg 110 by a first sputtering process has a cooling time and may reduce internal stress before a next alloy layer is deposited. A cooling time may be controlled by a rotation speed and size of the first jig 311. After one layer is deposited on the thermoelectric leg 110, a subsequent cooling time (OFF time) may be about 73.5±10 sec.

After process 710 is completed, a total thickness of the first diffusion barrier layer 130a in which a plurality of nickel (Ni)-chromium (Cr) alloy layers are stacked may have about 1.0 μm to 10.0 μm. For example, a thickness of the first diffusion barrier layer 130a may have about 3.0 μm to 5.0 μm.

According to an embodiment, a deposition layer (e.g., the first diffusion barrier layer 130a) formed through the first sputtering unit 320 in process 720 may be a multi-layer in which a plurality of nickel (Ni)-vanadium (V) alloy layers are stacked. One nickel (Ni)-vanadium (V) alloy layer may be formed when the thermoelectric leg 110 mounted on the second jig 312 rotates once, and the multi-layer may be formed as the thermoelectric leg 110 mounted on the second jig 312 rotates multiple times. For example, when the thermoelectric leg 110 mounted on the second jig 312 rotates multiple times, one layer of the multi-layer may be deposited on the thermoelectric leg 110 by a first sputtering process whenever it is positioned in the first section adjacent to the first sputtering unit 320 (ON time). A sputtering ON time for depositing one layer on the thermoelectric leg 110 may be about 6.5±2 sec. An alloy amount of vanadium (V) in the nickel (Ni)-vanadium (V) alloy layer may be 10±5 weight percent (wt %) relative to total weight. An alloy amount of nickel (Ni) in the nickel (Ni)-vanadium (V) alloy layer may be 90±5 weight percent (wt %) relative to total weight. For example, when the thermoelectric leg 110 mounted on the second jig 312 rotates multiple times, whenever it is positioned in the second section away from the first sputtering unit 320 (OFF time), one layer of the multi-layer on the thermoelectric leg 110 by a first sputtering process has a cooling time and may reduce internal stress before a next alloy layer is deposited. A cooling time may be controlled by a rotation speed and size of the first jig 311. After one layer is deposited on the thermoelectric leg 110, a subsequent cooling time (OFF time) may be about 73.5±10 sec.

After process 720 is completed, a total thickness of the first diffusion barrier layer 130a in which a plurality of nickel (Ni)-vanadium (V) alloy layers are stacked may have about 1.0 μm to 10.0 μm. For example, a thickness of the first diffusion barrier layer 130a may have about 3.0 μm to 5.0 μm.

Subsequently, according to process 800 (referring to FIGS. 7C and 7D), the second diffusion barrier layer 130b may be deposited on upper and/or lower sides of the first diffusion barrier layer 130a. For example, the second diffusion barrier layer 130b may include a 2-1th diffusion barrier layer (e.g., the 2-1th diffusion barrier layer 130ba of FIG. 3) disposed on an upper side of the 1-1th diffusion barrier layer 130aa, and a 2-2th diffusion barrier layer (e.g., the 2-2th diffusion barrier layer 130bb of FIG. 3) disposed on a lower side of the 1-2th diffusion barrier layer 130ab. The 2-1th diffusion barrier layer 130ba and the 2-2th diffusion barrier layer 130bb may be formed with thicknesses and materials corresponding to each other.

According to an embodiment, the second diffusion barrier layer 130b may include one or more metal powders selected from the group consisting of gold (Au), silver (Ag), tin (Sn), chromium (Cr), platinum (Pt), titanium (Ti), tungsten (W), silicon (Si), manganese (Mn), iron (Fe), cobalt (Co), copper (Cu), or molybdenum (Mo). According to an embodiment, the second diffusion barrier layer 130b may include a layer formed of a single metal. For example, the second diffusion barrier layer 130b may be a single metal layer formed of gold (Au), silver (Ag), or tin (Sn). For example, according to process 810, the second diffusion barrier layer 130b may form a structure in which a plurality of single metal layers formed of gold (Au) are stacked. For example, according to process 820, the second diffusion barrier layer 130b may form a structure in which a plurality of single metal layers formed of tin (Sn) are stacked. Process 810 or process 820 may be selectively performed.

According to an embodiment, the second diffusion barrier layer 130b is performed by a dry deposition process (e.g., sputtering process), and a sputtering device for this may include a jig 310 and a second sputtering unit 330 spaced apart at an edge portion of the jig 310. Referring to FIGS. 7C and 7D, the jig 310 may include a circular first jig 311 that rotates about a central axis O and a second jig 312 disposed on one side of the first jig 311 for fixing a sample (e.g., the thermoelectric leg 110). For example, the first jig 311 may rotate itself about the central axis O. For example, the second jig 312 is fixedly disposed at an edge of the first jig 311, and may rotate about the central axis O in response to rotation of the first jig 311 while the thermoelectric leg 110 is mounted. The second jig 312 may move past the first sputtering unit 320 and the second sputtering unit 330.

According to an embodiment, in process 800, the thermoelectric leg 110 (or the first diffusion barrier layer 130a) mounted on the second jig 312 moves to be adjacent to the second sputtering unit 330, and as the second sputtering unit 330 operates, the second diffusion barrier layer 130b may be deposited on the first diffusion barrier layer 130a. For example, as the thermoelectric leg 110 (or the first diffusion barrier layer 130a) mounted on the second jig 312 rotates and moves, whenever it is adjacent to the second sputtering unit 330 (e.g., when positioned in a third section C, ON time), one layer of a multi-layer (e.g., the first single metal layer 133 of the second diffusion barrier layer 130b) may be deposited on the first diffusion barrier layer 130a by a second sputtering process. Subsequently, when the thermoelectric leg 110 (or the first diffusion barrier layer 130a) mounted on the second jig 312 additionally rotates and moves away from the second sputtering unit 330 (e.g., when positioned in a fourth section D, OFF time), a cooling time is provided to one layer of the multi-layer (e.g., the first single metal layer 133 of the second diffusion barrier layer 130b) deposited on the first diffusion barrier layer 130a, and the single metal layer 133 is stably formed so that internal stress may be decreased. The reduction of the internal stress may limit (reduce or prevent) physical damage (e.g., cracking, warping, or bending) of the second diffusion barrier layer 130b. According to an embodiment, a cooling time may be formed to be longer than a deposition time.

According to an embodiment, a deposition layer (e.g., the second diffusion barrier layer 130b) to be formed through the second sputtering unit 330 in process 810 may be a multi-layer in which a plurality of Au (gold) single metal layers are stacked. One Au (gold) single metal layer may be formed when the thermoelectric leg 110 (or the first diffusion barrier layer 130a) mounted on the second jig 312 rotates once, and the multi-layer may be formed by the thermoelectric leg 110 (or the first diffusion barrier layer 130a) mounted on the second jig 312 rotating multiple times. For example, when the thermoelectric leg 110 (or the first diffusion barrier layer 130a) mounted on the second jig 312 rotates multiple times, one layer of the multi-layer may be deposited on the first diffusion barrier layer 130a by a second sputtering process whenever it is positioned in the third section C adjacent to the second sputtering unit 330 (ON time). A sputtering ON time for depositing one layer on the first diffusion barrier layer 130a may be about 6.5±2 sec. For example, when the thermoelectric leg 110 (or the first diffusion barrier layer 130a) mounted on the second jig 312 rotates multiple times, whenever it is positioned in the fourth section D away from the second sputtering unit 330 (OFF time), one layer of the multi-layer on the thermoelectric leg 110 by a second sputtering process has a cooling time and may reduce internal stress before a next single metal layer is deposited. A cooling time may be longer than a deposition time. A cooling time may be controlled by a rotation speed and size of the first jig 311. After one layer is deposited on the first diffusion barrier layer 130a, a subsequent cooling time (OFF time) may be about 73.5±10 sec.

After process 810 is completed, a total thickness of the second diffusion barrier layer 130b in which a plurality of Au (gold) single metal layers are stacked may have about 0.01 μm to 3.0 μm. For example, a thickness of the second diffusion barrier layer 130b may have about 0.01 μm to 0.5 μm.

According to an embodiment, a deposition layer (e.g., the second diffusion barrier layer 130b) to be formed through the second sputtering unit 330 in process 820 may be a multi-layer in which a plurality of tin (Sn) single metal layers are stacked. One tin (Sn) single metal layer may be formed when the thermoelectric leg 110 (or the first diffusion barrier layer 130a) mounted on the second jig 312 rotates once, and the multi-layer may be formed by the thermoelectric leg 110 (or the first diffusion barrier layer 130a) mounted on the second jig 312 rotating multiple times. For example, when the thermoelectric leg 110 (or the first diffusion barrier layer 130a) mounted on the second jig 312 rotates multiple times, one layer of the multi-layer may be deposited on the first diffusion barrier layer 130a by a second sputtering process whenever it is positioned in the third section C adjacent to the second sputtering unit 330 (ON time). A sputtering ON time for depositing one layer on the first diffusion barrier layer 130a may be about 6.5±2 sec. For example, when the thermoelectric leg 110 (or the first diffusion barrier layer 130a) mounted on the second jig 312 rotates multiple times, whenever it is positioned in the fourth section D away from the second sputtering unit 330 (OFF time), one layer of the multi-layer on the thermoelectric leg 110 by a second sputtering process has a cooling time and may reduce internal stress before a next single metal layer is deposited. A cooling time may be longer than a deposition time. A cooling time may be controlled by a rotation speed and size of the first jig 311. After one layer is deposited on the first diffusion barrier layer 130a, a subsequent cooling time (OFF time) may be about 73.5±10 sec.

After process 820 is completed, a total thickness of the second diffusion barrier layer 130b in which a plurality of tin (Sn) single metal layers are stacked may have about 0.01 μm to 3.0 μm. For example, a thickness of the second diffusion barrier layer 130b may have about 0.01 μm to 0.5 μm.

According to process 900, after a sputtering process is completed, a process of releasing a vacuum state inside a chamber and collecting thermoelectric element 100 may be performed. For example, by slowly releasing a vacuum state inside a chamber to balance with external atmospheric pressure, damage or defects of the thermoelectric element 100 that may occur due to sudden pressure changes may be prevented. As a vacuum state release condition, a vacuum degree inside a chamber proceeds to atmospheric pressure, 7.6×10² torr, and a process may be performed while identifying that foreign objects inside the chamber do not attach to the thermoelectric element 100 when releasing a vacuum state.

According to process 1000, a cleaning and inspection process of the thermoelectric element 100 including a diffusion barrier layer (e.g., the first diffusion barrier layer 130a and/or the second diffusion barrier layer 130b) may be performed. In the thermoelectric element 100 collected from the sputtering chamber 300, foreign objects such as particles, thin film residues, or other impurities remaining on a surface of the thermoelectric element 100 may be removed, and a cleaning process may be performed by at least one of ultrasonic cleaning, ion water cleaning, or alcohol cleaning. The thermoelectric element 100 on which cleaning is completed may determine thickness, uniformity, adhesion state, or abnormalities such as surface defects of deposition layers (e.g., thin films) through analytical equipment. The analytical equipment may include equipment capable of enlarging a portion of deposition layers, such as an optical microscope or a scanning electron microscope (SEM).

According to an embodiment, by stacking a diffusion barrier layer 130 (e.g., the first diffusion barrier layer 130a and/or the second diffusion barrier layer 130b) on the thermoelectric leg 110 in an inline manner by rotary sputtering equipment, a thermoelectric element 100 advantageous for multi-layer generation may be provided.

Unlike linearly disposed multiple sputtering units, rotary sputtering equipment may simplify processes, downsize equipment, and/or reduce process costs by disposing only one sputtering unit for forming each diffusion barrier layer (e.g., the first sputtering unit 320 for the first diffusion barrier layer 130a and the second sputtering unit 330 for the second diffusion barrier layer 130b). Further, a desired thickness of a diffusion barrier layer may be easily controlled according to a rotation speed of the jig 310, thereby enhancing work performance efficiency.

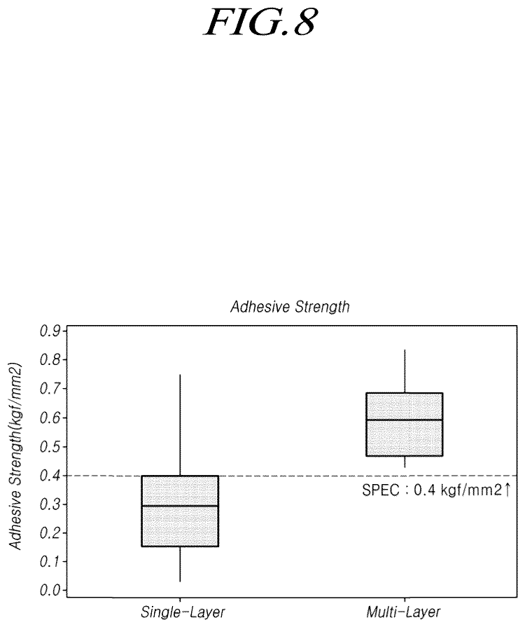

FIG. 8 is a graph illustrating experimental results of adhesive strength between a diffusion barrier layer configured as a single-layer and a diffusion barrier layer configured as a multi-layer according to an embodiment of the disclosure.

The configuration of the thermoelectric element 100 of FIG. 8 may be identical in whole or part to the configuration of the thermoelectric element 100 of FIGS. 2 to 7.

The embodiment of FIG. 8 may be selectively combined with the embodiments of FIGS. 1 to 7, FIG. 8, and FIG. 9.

According to an embodiment, a thermoelectric element (e.g., the thermoelectric element 100 of FIGS. 2 and 3) may include a diffusion barrier layer (e.g., the diffusion barrier layer 130 of FIGS. 2 and 3) forming a multi-layer. The thermoelectric element 100 may include a thermoelectric leg (e.g., the thermoelectric leg 110 of FIGS. 2 and 3) (e.g., Peltier leg), a first diffusion barrier layer (e.g., the first diffusion barrier layer 130a of FIGS. 2 and 3), and/or a second diffusion barrier layer (e.g., the second diffusion barrier layer 130b of FIGS. 2 and 3).

According to an embodiment, the thermoelectric element 100 may include a thermoelectric leg 110 and a first diffusion barrier layer 130a disposed on an upper side or a lower side of the thermoelectric leg 110. According to an embodiment, the thermoelectric element 100 may include a thermoelectric leg 110, a first diffusion barrier layer 130a disposed on an upper side or a lower side of the thermoelectric leg 110, and a second diffusion barrier layer 130b disposed on one side of the first diffusion barrier layer 130a.

According to an embodiment, the first diffusion barrier layer 130a and/or the second diffusion barrier layer 130b may form a multi-layer. A multi-layer of the first diffusion barrier layer 130a may be a structure in which a plurality of alloy layers formed of a nickel (Ni)-chromium (Cr) alloy or a nickel (Ni)-vanadium (V) alloy are stacked. A multi-layer of the second diffusion barrier layer 130b may be a structure in which a plurality of single metal layers formed of gold (Au), silver (Ag), or tin (Sn) are stacked.

According to an embodiment, a multi-layer of the first diffusion barrier layer 130a and/or the second diffusion barrier layer 130b may be formed by a dry deposition process. A multi-layer of the first diffusion barrier layer 130a and/or the second diffusion barrier layer 130b may be formed by providing multiple sputtering processes and a cooling time after a sputtering process. A cooling time may provide a deposition time during which multi-layers (e.g., alloy layers or single metal layers) of the first diffusion barrier layer 130a deposited on the thermoelectric leg 110 and/or the second diffusion barrier layer 130b deposited on the first diffusion barrier layer 130a may be stably formed. Accordingly, a completed thermoelectric element 100 may have physical damage (e.g., cracking, warping, or bending) limited (decreased or prevented).

According to an embodiment, a multi-layer of the first diffusion barrier layer 130a and/or the second diffusion barrier layer 130b may provide strong adhesive strength compared to a single-layer, which is a configuration of a general thermoelectric element. The strong adhesive strength may occur as internal stress of the thermoelectric element 100 is decreased.

Table 1 below illustrates experimental data values for identifying adhesive strength of a thermoelectric element in which a diffusion barrier layer is configured as a single-layer.

TABLE 1
Single-Layer

| | | tensile strength | |
|---|---|---|---|
| NO. | type | measurement value | converted value |
| 1 | N-type | 0.550 | 0.216 |
| 2 | | 2.025 | 0.796 |
| 3 | | 1.010 | 0.397 |
| 4 | | 0.925 | 0.354 |
| 5 | | 0.875 | 0.344 |
| 6 | | 0.850 | 0.334 |
| 7 | | 2.325 | 0.914 |
| 8 | | 1.425 | 0.560 |
| 9 | | 2.425 | 0.953 |
| 10 | | 0.825 | 0.324 |
| 11 | | 0.625 | 0.246 |
| 12 | | 1.900 | 0.747 |
| 13 | | 0.625 | 0.246 |
| 14 | | 0.200 | 0.079 |
| 15 | | 0.400 | 0.157 |
| 16 | P-type | 1.400 | 0.550 |
| 17 | | 1.950 | 0.767 |
| 18 | | 0.325 | 0.128 |
| 19 | | 0.300 | 0.118 |
| 20 | | 1.425 | 0.560 |
| 21 | | 0.600 | 0.236 |
| 22 | | 0.375 | 0.147 |
| 23 | | 0.100 | 0.039 |
| 24 | | 0.950 | 0.374 |
| 25 | | 0.275 | 0.108 |
| 26 | | 0.800 | 0.315 |
| 27 | | 0.725 | 0.285 |
| 28 | | 0.850 | 0.334 |
| 29 | | 0.825 | 0.324 |
| 30 | | 0.100 | 0.039 |
| 31 | | 0.450 | 0.177 |
| 32 | | 0.950 | 0.374 |
| 33 | | 1.125 | 0.442 |
| 34 | | 0.100 | 0.039 |
| 35 | | 0.750 | 0.285 |
| 36 | | 0.600 | 0.236 |
| 37 | | 0.500 | 0.197 |
| 38 | | 0.475 | 0.187 |
| 39 | | 0.100 | 0.019 |
| | | Ave. | 0.333 |
| | | Max. | 0.953 |
| | | Min. | 0.039 |
| | | Stdev. | 0.241 |

Referring to Table 1, “NO” refers to examples of experimental samples, and for N-type thermoelectric elements, tensile strength measurement values of a diffusion barrier layer configured as a single-layer were identified through a total of 15 experimental samples, and for P-type thermoelectric elements, tensile strength measurement values of a diffusion barrier layer configured as a single-layer were identified through a total of 24 experimental samples. Tensile strength measurement values of N-type thermoelectric elements and tensile strength measurement values of P-type thermoelectric elements including the same type of diffusion barrier layer (e.g., deposition layer) showed similar values.

Referring to Table 1 and FIG. 8, it was identified that an average value of converted adhesive strength of a thermoelectric element including a single-layer diffusion barrier layer is 0.333 kgf/mm².

Table 2 below illustrates experimental data values for identifying adhesive strength of a thermoelectric element in which a diffusion barrier layer is configured as a multi-layer.

TABLE 2
Multi-Layer

| | | tensile strength | |
|---|---|---|---|
| NO | type | measurement value | converted value |
| 1 | N-type | 1.100 | 0.432 |
| 2 | | 1.100 | 0.432 |
| 3 | | 2.050 | 0.806 |
| 4 | | 1.225 | 0.482 |
| 5 | | 1.525 | 0.600 |
| 6 | | 1.500 | 0.590 |
| 7 | | 1.775 | 0.698 |
| 8 | | 2.100 | 0.826 |
| 9 | | 1.425 | 0.560 |
| 10 | | 1.475 | 0.580 |
| 11 | P-type | 1.600 | 0.629 |
| 12 | | 1.725 | 0.678 |
| 13 | | 1.150 | 0.452 |
| 14 | | 1.750 | 0.688 |
| 15 | | 1.825 | 0.718 |
| 16 | | 1.550 | 0.609 |
| 17 | | 1.750 | 0.688 |
| 18 | | 1.125 | 0.442 |
| 19 | | 1.175 | 0.462 |
| 20 | | 1.400 | 0.550 |
| | | Ave. | 0.596 |
| | | Max. | 0.826 |
| | | Min. | 0.432 |
| | | Stdev. | 0.121 |

Referring to Table 2, “NO” refers to examples of experimental samples, and for N-type thermoelectric elements, tensile strength measurement values of a diffusion barrier layer configured as a multi-layer were identified through a total of 10 experimental samples, and for P-type thermoelectric elements, tensile strength measurement values of a diffusion barrier layer configured as a multi-layer were identified through a total of 10 experimental samples. Tensile strength measurement values of N-type thermoelectric elements and tensile strength measurement values of P-type thermoelectric elements including the same type of diffusion barrier layer (e.g., deposition layer) showed similar values.

Referring to Table 2 and FIG. 8, it was identified that an average value of converted adhesive strength of a thermoelectric element including a multi-layer diffusion barrier layer is 0.4 kgf/mm² or more. For example, it was identified that an average value of converted adhesive strength of a thermoelectric element is 0.596 kgf/mm².

Referring to Tables 1, 2, and FIG. 8, it was identified that a thermoelectric element configured with a multi-layer diffusion barrier layer provides about twice the enhanced adhesive strength compared to a thermoelectric element configured with a single-layer diffusion barrier layer. Accordingly, the thermoelectric element 100 configured with a multi-layer diffusion barrier layer of the disclosure may provide high bonding stability performance with enhanced (decreased) internal stress.

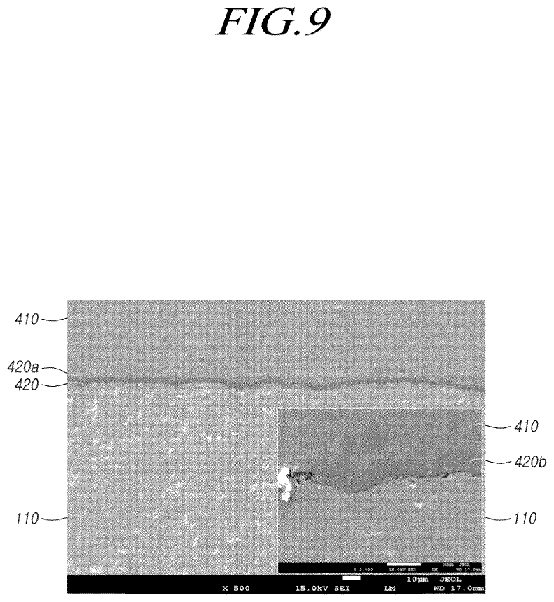

FIG. 9 is a view illustrating a comparative experiment related to thickness of a first diffusion barrier layer of a thermoelectric element according to an embodiment of the disclosure.

The configuration of the thermoelectric element 100 of FIG. 9 may be identical in whole or part to the configuration of the thermoelectric element 100 of FIGS. 2 to 8.

The embodiment of FIG. 9 may be selectively combined with the embodiments of FIGS. 1 to 8.

According to an embodiment, a thermoelectric element (e.g., the thermoelectric element 100 of FIGS. 2 and 3) may include a diffusion barrier layer (e.g., the diffusion barrier layer 130 of FIGS. 2 and 3) forming a multi-layer. The thermoelectric element 100 may include a thermoelectric leg (e.g., the thermoelectric leg 110 of FIGS. 2 and 3) (e.g., Peltier leg), a first diffusion barrier layer (e.g., the first diffusion barrier layer 130a of FIGS. 2 and 3), and/or a second diffusion barrier layer (e.g., the second diffusion barrier layer 130b of FIGS. 2 and 3).

According to an embodiment, the first diffusion barrier layer 130a and/or the second diffusion barrier layer 130b may form a multi-layer. A multi-layer of the first diffusion barrier layer 130a may be a structure in which a plurality of alloy layers formed of a nickel (Ni)-chromium (Cr) alloy or a nickel (Ni)-vanadium (V) alloy are stacked. A multi-layer of the second diffusion barrier layer 130b may be a structure in which a plurality of single metal layers formed of gold (Au), silver (Ag), or tin (Sn) are stacked.

According to an embodiment, the first diffusion barrier layer 130a may be deposited to a predetermined thickness or more considering soldering with electrodes (e.g., soldering with Sn (tin)). For example, a thickness of the first diffusion barrier layer 130a may have a thickness of about 3.0 μm or more. For example, a thickness of the first diffusion barrier layer 130a may have about 3.0 μm to 10.0 μm. For example, a thickness of the first diffusion barrier layer 130a may have about 3.0 μm to 5.0 μm.

Referring to FIG. 9, when the first diffusion barrier layer 130a disposed on the thermoelectric leg 110 is soldered with electrodes (e.g., soldering with Sn (tin)), it may be identified that the first diffusion barrier layer 130a remains according to thickness. The soldering was a result of performing reflow once, and temperature and time were Max 260° C. and about 1 min, respectively. FIG. 9(a) illustrates a case where a thickness of the first diffusion barrier layer 130a is 3.0 μm or more, and FIG. 9(b) illustrates a case where a thickness of the first diffusion barrier layer 130a is 1.0 μm or less.

Referring to FIG. 9(a), it may be identified that the first diffusion barrier layer 130a with a thickness of 3.0 μm or more, after soldering, partially diffuses into a Sn (tin) layer 410 and another portion thereof stably forms a plating layer 420. The portion (e.g., the diffusion layer 420a) of the first diffusion barrier layer 130a diffused into the Sn (tin) layer 410 may be identified to form a relatively blurred layer compared to the plating layer 420 that appears with distinct contrast.

Referring to FIG. 9(b), it may be identified that the first diffusion barrier layer 130a with a thickness of 1.0 μm or less (experimental results show that a thickness of Max 0.9 μm to 1.0 μm diffuses into the Sn (tin) layer 410 and disappears), after soldering, entirely diffuses into the Sn (tin) layer 410 and disappears. The first diffusion barrier layer 130a diffused into the Sn (tin) layer 410 may be identified as a diffusion layer 420b at a boundary surface of the thermoelectric material 100. When the first diffusion barrier layer 130a is depleted due to complete diffusion by soldering (e.g., when unable to form a plating layer), Sn—Te compound formation and module reliability degradation due to brittleness may occur.

Based on the experimental results, the first diffusion barrier layer 130a of the thermoelectric element 100 of the disclosure may be designed as a first diffusion barrier layer 130a having a thickness of 3.0 μm (1.0 μm×300%) or more, considering a safety margin of 300%. The first diffusion barrier layer 130a having a thickness of 3.0 μm or more is not eliminated (e.g., diffused into a solder layer) by soldering, and may form a stable layer of the thermoelectric element 100.

Hereinafter, a general configuration of a refrigerator in which the thermoelectric element 100 of the disclosure is used is described. However, the thermoelectric element 100 of the disclosure may be easily modified and applied to various home appliances in which the thermoelectric elements are utilized, such as an air purifying humidifier, a robot cleaner, a cooking device, or a washer, in addition to refrigerators.

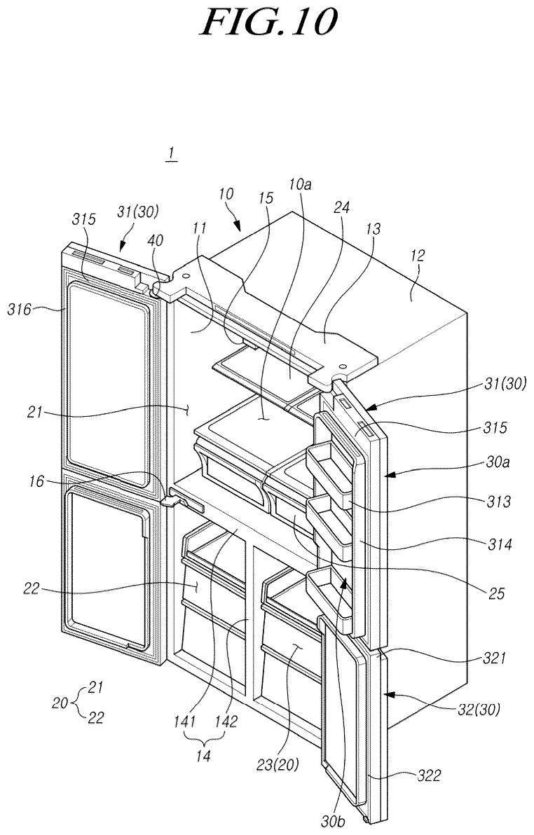

FIG. 10 is a perspective view illustrating a refrigerator according to an embodiment of the disclosure;

Referring to FIG. 10, a refrigerator 1 may include a main body 10, a storage compartment 20, a door 30, or a cold air supply device.

According to an embodiment, the storage compartment 20 may be partitioned into several spaces inside the main body 10. The door 30 may be disposed on the front surface of the main body 10 to open and close the storage compartment 20. The cold air supply device may be provided inside the main body 10 to supply cold air to, e.g., the storage compartment 20.

According to an embodiment, the main body 10 may include an inner housing 11 and/or an outer housing 12. The inner housing 11, e.g., may be provided to form an exterior of the storage compartment 20. The inner housing 11 may be integrally injection-molded with, e.g., a plastic material. The outer housing 12, e.g., may be provided to form at least a portion of the exterior of the refrigerator 1. The outer housing 12 may be formed of, e.g. a metal material having excellent durability and aesthetics. A receiving space may be formed between the inner housing 11 and the outer housing 12. A main body insulator (not shown) for insulating the storage compartment 20 may be provided in a portion of the receiving space.

According to an embodiment, the cold air supply device may generate cold air using a cooling circulation cycle for compressing, condensing, expanding, and evaporating the refrigerant.

According to an embodiment, the storage compartment 20 may be partitioned into a plurality of compartments by a partition wall 14. The storage compartment 20 may be formed by the inner housing 11 and the partition wall 14 of the main body 10. A plurality of shelves 24 or storage containers 25 may be provided inside the storage compartment 20 to store food or the like. The plurality of shelves 24 and the storage container 25 may be, e.g., removable.

According to an embodiment, the storage compartment 20 may be divided into a plurality of storage compartments 21, 22, and 23 by the partition wall 14. For example, as illustrated, the storage compartment 20 may include one first storage compartment 21 (e.g., an upper storage compartment) positioned at an upper portion, and a second storage compartments 22 (e.g., a lower storage compartment) and a third storage compartment 23 (e.g., a lower storage compartment) positioned at a lower portion.

According to an embodiment, the partition wall 14 may include a first partition wall 141 and a second partition wall 142. The partition wall 14 may have, e.g., a T-shaped cross section. The first partition wall 141 may be provided horizontally to divide, e.g., the first storage compartment 21 and the second and third storage compartments 22 and 23. The second partition wall 142 may be provided vertically to divide, e.g., the second storage compartment 22 and the third storage compartment 23. The second partition wall 142 may be formed to protrude downward from, e.g., the first partition wall 141. The illustrated second partition wall 142 is formed to protrude from the center of the first partition wall 141, but the disclosure is not limited thereto, and the sizes of the second storage compartment 22 and the third storage compartment 23 may vary depending on the position of the second partition wall 142.

The first storage compartment 21 of the illustrated storage compartment 20 may be used as a refrigerating chamber, and the second and third storage compartments 22 and 23 may be used as freezing chambers, but the disclosure is not limited thereto, and the position and number of each of the refrigerating chamber and the freezing chamber may vary depending on the user's needs.

According to an embodiment, the number, size, or shape of the storage compartment 20 may vary depending on the shape or position of the partition wall 14. The freezing compartment may be maintained at about minus 20 degrees Celsius, and the refrigerating compartment may be maintained at about 3 degrees Celsius. The storage compartment 20 may be insulated by, e.g., a partition wall 14.

According to an embodiment, the storage compartment 20 may be partitioned left and right by one vertical partition wall. Here, the vertical partition wall may be formed so that one end is in contact with the upper portion of the inner housing 11 and the other end is in contact with the lower portion of the inner housing 11. The size of the storage compartment 20 partitioned left and right may vary depending on the position of the vertical partition wall. For example, the storage compartment 20 having the vertical partition wall provided in the middle and partitioned left and right may be provided in mirror symmetry. According to an embodiment, there may be a plurality of vertical partition walls. When there are a plurality of vertical partition walls, three or more storage compartments 20 may be provided in the left-right direction.

According to an embodiment, the storage compartment 20 may be partitioned up and down only by one horizontal partition wall. In other words, the storage compartment 20 may be partitioned into two, e.g., the upper storage compartment and the lower storage compartment. Here, the horizontal partition wall may be formed so that one end thereof is in contact with the left portion of the inner housing 11 and the other end thereof is in contact with the right portion of the inner housing 11. The size of the storage compartment 20 partitioned up and down may vary depending on the position of the horizontal partition wall. According to an embodiment, there may be a plurality of horizontal partition walls. When there are a plurality of horizontal partition walls, three or more storage compartments 20 may be provided in the up-down direction. In addition to the above-described embodiment, a plurality of storage compartments 20 of various types may be configured according to the shape and number of partition walls 14.

According to an embodiment, the door 30 may include a first door 31 (e.g., an upper door) or a second door 32 (e.g., a lower door) as illustrated. The door 30 may be provided to open and close, e.g., the opening 10a of the main body 10. For example, a pair of first doors 31 (e.g., double door type) may be provided to open and close the first storage compartment 21. A pair of second doors 32 (e.g., double door type) may be provided to open or close, e.g., the second storage compartment 22 or the third storage compartment 23. Further, the number and shape of the doors 30 may vary depending on the number and shape of the storage compartment 20, and the door 30 may be configured in a sliding manner as well as a manner of rotating about the hinge 16.

According to an embodiment, a rotating bar 316 may be provided on one of the pair of first doors 31. The rotating bar 316 may be disposed, e.g., on a side opposite to a side of one of the pair of first doors 31 forming a rotation shaft. The rotation bar 316 may be provided such that, e.g., a rotation shaft is fixed to a side surface of one of the pair of first doors 31 to be rotatable about the rotation shaft. The rotating bar 316 may be provided to be positioned in the middle of the front surface of the main body 10 when one of the pair of first doors 31 is in a closed state. The rotating bar 316 may seal a gap between the pair of first doors 31 when the pair of first doors 31 are closed. The main body 10 may be provided with a rotating bar guide 15 for guiding the movement of the rotating bar 316 when one of the pair of first doors 31 is closed.

According to an embodiment, the door 30 (e.g., the first door 31 or the second door 32) may include a door panel 30a or a door body 30b. The door panel 30a and the door body 30b may be detachably coupled to each other.

According to an embodiment, for example, one side of the door body 30b may be fixed to the main body 10 by the hinge 16. The door body 30b may be provided to be rotatable about the main body 10. The door panel 30a may form, e.g., a portion of the front exterior of the refrigerator 1. The door panel 30a may play an important role for aesthetics, especially when the refrigerator 1 is disposed indoors. Accordingly, the user may decorate the front exterior of the refrigerator 1 as desired by replacing it with a door panel 30a having a different color or design. According to an embodiment, the door panel 30a and the door body 30b may be integrally formed with each other.

Hereinafter, for convenience of description, only one first door 31 and one second door 32 are described, and a description of the remaining first door 31 and the remaining second door 32 is omitted. However, the first door 31 and the second door 32, which are not described, may be substantially the same as the first door 31 and the second door 32, which are described below, except that they are provided to be symmetrical to each other. Further, the same configuration as that of the first door 31 may be applied to the second door 32, and a detailed description thereof may be omitted.

According to an embodiment, the first door 31 may include a first door handle (not shown), a first door shelf 313, a first shelf support 314, or a first gasket 315. The first door 31 may be rotatably coupled to the main body 10 to open and close at least a portion of the first storage compartment 21. The user may open and close the first door 31 using the first door handle. The first door handle may be recessed in the bottom surface of the first door 31 or may protrude from the front surface of the first door 31, but the disclosure is not limited thereto.

According to an embodiment, the first door shelf 313 may be provided to receive, e.g., food. First shelf supports 314 may be provided on both left and right sides of the first door shelf 313 to support the first door shelf 313. The first shelf support 314 may extend vertically from, e.g., the first door 31. In other words, the first shelf support 314 may be provided to protrude backward from the rear surface of the first door 31 and extend in the up-down direction. For example, the first shelf support 314 may be detachably provided on the first door 31 as a separate component, or may be integrally formed with the first door 31. The first shelf support 314 may be formed to protrude rearward from, e.g., the rear surface of the door body 30b.

According to an embodiment, the first gasket 315 may be provided to surround, e.g., a rear edge of the first door 31. Specifically, the first gasket 315 may be provided to surround an edge of the door body 30b. The first gasket 315 may be provided to seal a gap with the main body 10 in a state in which the first door 31 is closed.

According to an embodiment, the second door 32 may include a second door handle 321 or a second gasket 322. The second door 32 may be rotatably coupled to the main body 10 to open and close the second storage compartment 22 or the third storage compartment 23. The user may open and close the second door 32 using the second door handle 321. The second door handle 321 may be recessed in the upper surface of the second door 32 or may protrude from the front surface of the second door 32, but the disclosure is not limited thereto.

According to an embodiment, the second gasket 322 may be provided to surround, e.g., a rear edge of the second door 32. The second gasket 322 may be provided to seal a gap with the main body 10 in a state in which the second door 32 is closed.

Although not illustrated, the second door 31 may further include all or some of the same components as the first door shelf 313 and the first shelf support 314 of the first door 32.

According to an embodiment, the refrigerator 1 may include a top table 13 provided on an upper portion of the main body 10. The top table 13 may be coupled to an upper portion of the outer housing 12. For example, the top table 13 may be coupled to the upper surface of the outer housing 12. For example, the top table 13 may be fixed to the outer housing 12.

According to an embodiment, the top table 13 may cover the hinge bracket 40 of the upper door. In this sense, the top table 13 may be referred to as a hinge bracket cover.

According to an embodiment, the top table 13 may cover various electronic components. A receiving space in which various electronic components are received may be formed inside the top table 13. For example, the top table 13 may cover the door driver 400 to be described below, and the door driver 400 may be received inside the top table 13. Accordingly, the top table 13 may be referred to as a door driving cover.

Although the refrigerator 1 according to an embodiment of the disclosure has been described as an example of the disclosure assuming that the refrigerator 1 is an indirect cooling-type refrigerator, the spirit of the disclosure is not limited thereto and may also be applied to a direct cooling-type refrigerator.

Generally, a thermoelectric element may include thermoelectric legs classified as N-type and P-type, and electrodes electrically connected to the thermoelectric legs. The thermoelectric legs may undergo soldering to connect with the electrodes. When direct soldering is performed between one side of a thermoelectric leg and an electrode, an intermetallic compound (IMC) is formed by thermal diffusion, causing brittleness (e.g., increased internal stress) in thermoelectric leg, which may frequently cause element destruction.

To reduce internal stress of the thermoelectric element, a diffusion barrier layer may be disposed on a thermoelectric leg, but a general diffusion barrier layer (e.g., a single-layer diffusion barrier layer) has poor adhesive strength with a thermoelectric leg, which may reduce durability.

A thermoelectric element according to an embodiment of the disclosure may provide a stable thermoelectric element by depositing a plurality of diffusion barrier layers on a thermoelectric leg through a dry deposition process.

A thermoelectric element according to an embodiment of the disclosure may provide a thermoelectric element with enhanced durability by configuring a diffusion barrier layer formed as a multi-layer (e.g., a layer in which a plurality of alloy layers and/or single metal layers are stacked), thereby reducing internal stress and increasing adhesive strength between the diffusion barrier layer and thermoelectric leg.

A thermoelectric element according to an embodiment of the disclosure includes a diffusion barrier layer, and the diffusion barrier layer may provide a multi-layer in which a plurality of alloy layers formed of a nickel (Ni)-chromium (Cr) alloy or a nickel (Ni)-vanadium (V) alloy are stacked. The diffusion barrier layer may form a thermoelectric element with enhanced (decreased) internal stress.

A thermoelectric element according to an embodiment of the disclosure includes a diffusion barrier layer, and the diffusion barrier layer may provide a multi-layer in which a plurality of single metal layers formed of gold (Au), silver (Ag), or tin (Sn) are stacked. The diffusion barrier layer may form a thermoelectric element with enhanced (decreased) internal stress.

A thermoelectric element according to an embodiment of the disclosure provides a diffusion barrier layer through a dry deposition process, so that an insulation film on a side of the thermoelectric element may be excluded. Accordingly, the thermoelectric element may provide simplified manufacturing processes, enhanced productivity, cost reduction due to manufacturing cost reduction, and environmentally friendly processes.

A thermoelectric element according to an embodiment of the disclosure forms a diffusion barrier layer forming a multi-layer to enhance (reduce) internal stress, thereby providing stable and efficient performance of home appliances (e.g., refrigerators).

Effects obtainable from the disclosure are not limited to the above-mentioned effects, and other effects not mentioned may be apparent to one of ordinary skill in the art from the following description.

A thermoelectric element 100 according to an embodiment of the disclosure may include a Bi—Te based thermoelectric leg 110, a first diffusion barrier layer 130a disposed on an upper side and/or a lower side of the thermoelectric leg, the first diffusion barrier layer (130a) comprising a multi-layer including a plurality of stacked alloy layers 131, each of the stacked alloy layers having a thickness of 1 nm to 30 nm and including a nickel (Ni)-chromium (Cr) alloy or a nickel (Ni)-vanadium (V) alloy, and a second diffusion barrier layer disposed on a side of the first diffusion barrier layer, the second diffusion barrier layer including gold (Au), silver (Ag), tin (Sn), or a combination thereof.

According to an embodiment, the second diffusion barrier layer 130b may include a multi-layer including a plurality of stacked single metal layers 133, each of the stacked single metal layers including gold (Au), silver (Ag), tin (Sn), or a combination thereof, and having a thickness of 1 nm to 30 nm.

According to an embodiment, each of the stacked alloy layers 131 may have a thickness of 13 nm to 15 nm, and/or each of the stacked single metal layers 133 may have a thickness of 13 nm to 15 nm.

According to an embodiment, in the nickel (Ni)-chromium (Cr) alloy of the first diffusion barrier layer 130a, a chromium (Cr) content is 20±10 weight percent (wt %) relative to a total weight of the nickel (Ni)-chromium (Cr) alloy.

According to an embodiment, in the nickel (Ni)-vanadium (V) alloy of the first diffusion barrier layer 130a, a vanadium (V) content is 10±5 weight percent (wt %) relative to a total weight of the nickel (Ni)-vanadium (V) alloy.

According to an embodiment, a thickness of the first diffusion barrier layer 130a may be greater than a thickness of the second diffusion barrier layer 130b.

According to an embodiment, the first diffusion barrier layer 130a may have a thickness of 1.0 μm to 10.0 μm.

According to an embodiment, the first diffusion barrier layer 130a may have a thickness of 3.0 μm to 5.0 μm.

According to an embodiment, the second diffusion barrier layer 130b may have a thickness of 0.01 μm to 3.0 μm.

According to an embodiment, the first diffusion barrier layer 130a and/or the second diffusion barrier layer 130b may be formed by a dry deposition process.

According to an embodiment, in the dry deposition process, when forming the multi-layer of the first diffusion barrier layer 130a or the second diffusion barrier layer 130b, a cooling time is configured to be performed longer than a deposition time of a sputtering process.

According to an embodiment, the first diffusion barrier layer 130a may include a 1-1th diffusion barrier layer 130aa deposited on an upper surface of the thermoelectric leg 110, and a 1-2th diffusion barrier layer 130ab deposited on a lower surface of the thermoelectric leg 110.

According to an embodiment, the second diffusion barrier layer 130b may include a 2-1th diffusion barrier layer 130ba deposited on an upper surface of the 1-1th diffusion barrier layer 130aa, and a 2-2th diffusion barrier layer 130bb deposited on a lower surface of the 1-2th diffusion barrier layer 130ab.

According to an embodiment, an adhesive strength of the multi-layer of the first diffusion barrier layer 130a may have a value of 0.4 kgf/mm² or more.

A refrigerator 1 according to an embodiment of the disclosure may include a main body 10, a door 30 rotatably connected to open and close the main body, a storage compartment 20 disposed inside the main body for storing food, and a cold air supply device configured to supply cold air to the storage compartment, the cold air supply device including a thermoelectric element that includes: a Bi—Te based thermoelectric leg 110, a first diffusion barrier layer 130a disposed on an upper side and/or a lower side of the thermoelectric leg, the first diffusion barrier layer (130a) comprising a multi-layer including a plurality of stacked alloy layers 131, each of the stacked alloy layers including a nickel (Ni)-chromium (Cr) alloy or a nickel (Ni)-vanadium (V) alloy, and a second diffusion barrier layer 130b disposed on a side of the first diffusion barrier layer, the second diffusion barrier layer including gold (Au), silver (Ag), tin (Sn), or a combination thereof.

According to an embodiment, the second diffusion barrier layer 130b may include a multi-layer including a plurality of stacked single metal layers, each ot the stacked single metal layers including gold (Au), silver (Ag), tin (Sn), or a combination thereof.

According to an embodiment, each of the stacked alloy layers 131 may have a thickness of 13 nm to 15 nm, and/or each of the stacked single metal layers 131 may have a thickness of 13 nm to 15 nm.

According to an embodiment of the disclosure, a method of manufacturing a thermoelectric element 100 including a Bi—Te based thermoelectric leg, a first diffusion barrier layer on a side of the thermoelectric leg, the first diffusion barrier layer including: a multi-layer including a plurality of stacked alloy layers, each of the stacked alloy layers including a nickel (Ni)-chromium (Cr) alloy or a nickel (Ni)-vanadium (V) alloy, and a second diffusion barrier layer on a side of the first diffusion barrier layer, the second diffusion barrier layer including gold (Au), silver (Ag), tin (Sn), or a combination thereof, the method may comprise: plasma cleaning the thermoelectric leg; depositing the first diffusion barrier layer on the thermoelectric leg with a first sputtering unit; and depositing the second diffusion barrier layer on the first diffusion barrier layer with a second sputtering unit.

According to an embodiment, in forming the first diffusion barrier layer, thermoelectric leg may be mounted on a rotating jig and rotate a plurality of times.

According to an embodiment, in a first section A where thermoelectric leg is adjacent to the first sputtering unit, the alloy layer may be formed on the thermoelectric leg by sputtering.

According to an embodiment, in a second section B where thermoelectric leg is away from the first sputtering unit, a cooling time may be provided to reduce internal stress of the alloy layer.

According to an embodiment, the cooling time of the second section may be longer than a time for forming the alloy layer in the first section.

According to an embodiment, in forming the second diffusion barrier layer, thermoelectric leg and the first diffusion barrier layer may be mounted on a rotating jig and rotate a plurality of times.

According to an embodiment, in a third section C where the first diffusion barrier layer is adjacent to the second sputtering unit, the single metal layer may be formed on the first diffusion barrier layer by sputtering.

According to an embodiment, in a fourth section D where the first diffusion barrier layer is away from the second sputtering unit, a cooling time may be provided to reduce internal stress of the single metal layer.

According to an embodiment, the cooling time of the fourth section may be longer than a time for forming the single metal layer in the third section.

1. A thermoelectric element comprising:
a Bi—Te based thermoelectric leg;
a first diffusion barrier layer disposed on an upper side and/or a lower side of the thermoelectric leg, the first diffusion barrier layer comprising:
a multi-layer including a plurality of stacked alloy layers, each of the stacked alloy layers having a thickness of 1 nm to 30 nm and including a nickel (Ni)-chromium (Cr) alloy or a nickel (Ni)-vanadium (V) alloy; and
a second diffusion barrier layer disposed on a side of the first diffusion barrier layer, the second diffusion barrier layer including gold (Au), silver (Ag), tin (Sn), or a combination thereof.

2. The thermoelectric element of claim 1, wherein
the second diffusion barrier layer includes a multi-layer including a plurality of stacked single metal layers, each of the stacked single metal layers including gold (Au), silver (Ag), tin (Sn), or a combination thereof, and having a thickness of 1 nm to 30 nm.

3. The thermoelectric element of claim 2, wherein
each of the stacked alloy layers has a thickness of 13 nm to 15 nm, and/or
each of the stacked single metal layers has a thickness of 13 nm to 15 nm.

4. The thermoelectric element of claim 1, wherein
in the nickel (Ni)-chromium (Cr) alloy of the first diffusion barrier layer, a chromium (Cr) content is 20±10 weight percent (wt %) relative to a total weight of the nickel (Ni)-chromium (Cr) alloy.

5. The thermoelectric element of claim 1, wherein
in the nickel (Ni)-vanadium (V) alloy of the first diffusion barrier layer, a vanadium (V) content is 10±5 weight percent (wt %) relative to a total weight of the nickel (Ni)-vanadium (V) alloy layer.

6. The thermoelectric element of claim 1, wherein a thickness of the first diffusion barrier layer is greater than a thickness of the second diffusion barrier layer.

7. The thermoelectric element of claim 1, wherein a thickness of the first diffusion barrier layer is 1.0 μm to 10.0 μm.

8. The thermoelectric element of claim 1, wherein a thickness of the first diffusion barrier layer is 3.0 μm to 5.0 μm.

9. The thermoelectric element of claim 8, wherein a thickness of the second diffusion barrier layer is 0.01 μm to 3.0 μm.

10. The thermoelectric element of claim 1, wherein the first diffusion barrier layer and/or the second diffusion barrier layer is formed by a dry deposition process.

11. The thermoelectric element of claim 10, wherein in the dry deposition process, when forming the multi-layer of the first diffusion barrier layer or the second diffusion barrier layer, a cooling time is configured to be performed longer than a deposition time of a sputtering process.

12. The thermoelectric element of claim 1, wherein
the first diffusion barrier layer includes:
a 1-1th diffusion barrier layer deposited on an upper surface of the thermoelectric leg, and
a 1-2th diffusion barrier layer deposited on a lower surface of the thermoelectric leg.

13. The thermoelectric element of claim 12, wherein
the second diffusion barrier layer includes:
a 2-1th diffusion barrier layer deposited on an upper surface of the 1-1th diffusion barrier layer, and
a 2-2th diffusion barrier layer deposited on a lower surface of the 1-2th diffusion barrier layer.

14. The thermoelectric element of claim 1, wherein an adhesive strength of the multi-layer of the first diffusion barrier layer has a value of 0.4 kgf/mm2 or more.

15. A refrigerator comprising:
a main body;
a door rotatably connected to open or close the main body; a storage compartment disposed inside the main body for storing food; and
a cold air supply device configured to supply cold air to the storage compartment, the cold air supply device including a thermoelectric element that includes:
a Bi—Te based thermoelectric leg
a first diffusion barrier layer disposed on an upper side and/or a lower side of the thermoelectric leg, the first diffusion barrier layer including:
a multi-layer including a plurality of stacked alloy layers, each of the stacked alloy layers including a nickel (Ni)-chromium (Cr) alloy or a nickel (Ni)-vanadium (V) alloy, and
a second diffusion barrier layer disposed on a side of the first diffusion barrier layer, the second diffusion barrier layer including gold (Au), silver (Ag), tin (Sn), or a combination thereof.

16. The refrigerator of claim 15, wherein
the second diffusion barrier layer includes a multi-layer including a plurality of stacked single metal layers, each of the stacked single metal layers including gold (Au), silver (Ag), tin (Sn), or a combination thereof.

17. The refrigerator of claim 16, wherein
each of the stacked alloy layers has a thickness of 13 nm to 15 nm, and/or
each of the stacked single metal layers has a thickness of 13 nm to 15 nm.

18. A method of manufacturing a thermoelectric element including a Bi—Te based thermoelectric leg, a first diffusion barrier layer on a side of the thermoelectric leg, the first diffusion barrier layer including: a multi-layer including a plurality of stacked alloy layers, each of the stacked alloy layers including a nickel (Ni)-chromium (Cr) alloy or a nickel (Ni)-vanadium (V) alloy, and a second diffusion barrier layer on a side of the first diffusion barrier layer, the second diffusion barrier layer including gold (Au), silver (Ag), tin (Sn), or a combination thereof, the method comprising:
plasma cleaning the thermoelectric leg;
depositing the first diffusion barrier layer on the thermoelectric leg with a first sputtering unit; and
depositing the second diffusion barrier layer on the first diffusion barrier layer with a second sputtering unit.

19. The method of claim 18,
wherein in forming the first diffusion barrier layer, the thermoelectric leg mounted on a rotating jig and rotateed a plurality of times,
wherein in a first section where the thermoelectric leg is adjacent to the first sputtering unit, the alloy layer is formed on the thermoelectric leg by sputtering,
wherein in a second section where the thermoelectric leg is away from the first sputtering unit, the alloy layer is cooled for a cooling time to reduce internal stress of the alloy layer, and
wherein the cooling time of the second section is longer than a deposition time of the alloy layer in the first section.

20. The method of claim 19,
wherein in forming the second diffusion barrier layer, the thermoelectric leg and the first diffusion barrier layer are mounted on a rotating jig and rotate a plurality of times,
wherein in a third section where the first diffusion barrier layer is adjacent to the second sputtering unit, the single metal layer is formed on the first diffusion barrier layer by sputtering,
wherein in a fourth section where the first diffusion barrier layer is away from the second sputtering unit, the single metal layer is cooled for a cooling time to reduce internal stress of the single metal layer, and
wherein the cooling time of the fourth section is longer than a deposition time of the single metal layer in the third section.
